(19) United States
(12) Patent Application Publication
(10) Pub. No.: US 2010/0288338 A1
(43) Pub. Date: Nov. 18, 2010

(54) SOLAR CELL MODULE

(76) Inventors: Daiki Yamamoto, Osaka (JP); Ryutarou Watanabe, Osaka (JP)

Correspondence Address: NIXON & VANDERHYE, PC, 901 NORTH GLEBE ROAD, 11TH FLOOR, ARLINGTON, VA, 22203, US

(21) Appl. No.: 12/811,556

(22) PCT Filed: Dec. 25, 2008
(86) PCT No.: PCT/JP2008/073524

§ 371 Date: Jul. 2, 2010

(30) Foreign Application Priority Data
Jan. 8, 2008 (JP) 2008-001692

(51) Int. Cl. H01L 31/048

(52) U.S. Cl. 136/251

(57) ABSTRACT

A solar cell module (1a) includes main frame members (11a), each including a main retaining portion (20a) and a main wall portion (30a) that is connected to and extends downward below the main retaining portion (20a). The main retaining portion (20a) includes a main retaining wall (21) formed along a main side of a solar cell panel (9), and a main retaining upper piece (22) and a main retaining lower piece (23) that project inward from upper and lower ends of the main retaining wall (21), respectively, and engage and retain an edge portion of the solar cell panel (9) therebetween. The solar cell module (1a) also includes a main overhanging piece (24) that projects from the upper end of the main retaining wall (21) of the main retaining portion (20a) with a downward inclination toward the outside.

### TECHNICAL FIELD

The present invention relates to a solar cell module to be installed in places with gradual inclines such as a gently sloping roof.

### BACKGROUND ART

Generally, solar cell modules include a solar cell panel and frame members that retain the solar cell panel. Frame members with various structures are known to be used for such a solar cell module.

In cases of using a solar cell module with such frame members for housing, for example, the solar cell module is often installed in inclined places, such as a roof, in order to make full use of sunlight without waste. When a solar cell module is installed at an inclination in this way, during rain, for example, rainwater flows over the surface of the inclined solar cell module.

Thus, in order to prevent such rainwater from collecting on the surface of a solar cell module, various devices have been suggested for draining water, such as rainwater, that flows over the surface of a solar cell module, away from the solar cell module (see FIG. 3 of Patent Document 1, for example).

A solar cell module (solar energy converter) described in Patent Document 1 includes an upstream solar cell module and a downstream solar cell module that are installed adjacent to each other at an inclination, as shown in FIG. 3 of Patent Document 1. Moreover, the downstream solar cell module has an upper frame (frame member) 3 provided with a gutter portion 33, and the upstream solar cell module has a lower frame (frame member) 4 provided with a lug portion 42 that covers the upper surface of the gutter portion 33.

Doing so causes water that flows over the surface of the solar cell modules to be channeled from the end of the lug portion 42 of the lower frame 4 into the gutter portion 33 and drained away from the solar cell modules.

[Patent Document 1] JP10-169127 A

### DISCLOSURE OF INVENTION

### Problems to be Solved by the Invention

However, with the solar cell module described in Patent Document 1, the lug portion 42 of the lower frame 4 of the solar cell module is formed parallel to a solar cell panel 7 of the solar cell module. Therefore, if this solar cell module is installed in places with gradual inclines such as a gently sloping roof, water flowing over the surface of the solar cell module is likely to collect on the surface of the lug portion 42 of the lower frame 4 by the effect of surface tension.

As a result, the collected water reaches the surface of the solar cell panel 7 and can cause dust or the like in the air to adhere to the surface of the solar cell panel 7, thereby reducing the power power generation efficiency of the solar cell module.

In view of the above, the present invention has been conceived in order to improve such conditions and aims at providing a solar cell module that, when installed in places with gradual inclines such as a gently sloping roof, can prevent water flowing over the surface of the solar cell module from collecting on the surface of the solar cell module and can suppress a reduction in the power generation efficiency of the solar cell module.

### Means for Solving the Problems

A solar cell module of the present invention includes at least a pair of main frame members that retain a pair of opposing main sides of a solar cell panel, and is configured to be installed at a gradual inclination so that one of the main frame members is positioned lower than the other.

In the solar cell module, the main frame members each include a main retaining portion and a main wall portion. Among these, the main retaining portion includes a main retaining wall that runs along a main side of the solar cell panel, and a main retaining upper piece and a main retaining lower piece that project inward from upper and lower ends of the main retaining wall, respectively, and engage and retain an edge portion of the main side of the solar cell panel therebetween. The main wall portion is connected to and extends downward below the main retaining portion.

A feature of the solar cell module is that it is provided with a main overhanging piece. The main overhanging piece is included in at least the one of the main frame members that is positioned lower than the other and projects from the upper end of the main retaining wall of the main retaining portion at a downward inclination toward the outside, and its upper surface communicates with an upper surface of the main retaining upper piece.

The inclusion of such a main overhanging piece enables the solar cell module, when installed in places with gradual inclines such as a gently sloping roof, to cause water flowing over the surface of the solar cell module to flow down along the main overhanging piece that projects from the upper end of the main retaining wall of one of the main frame members at a downward inclination toward the outside.

It is thus possible to prevent the water flowing over the surface of the solar cell panel from collecting on the surface of the solar cell module and to suppress a reduction in the power generation efficiency of the solar cell module.

In the above solar cell module, both of the main frame members may be provided with the above-mentioned main overhanging piece. In this case, it is preferable that the solar cell module is installed at a plurality of locations adjacent to one another so that the ends of the main overhanging pieces of the main frame members of the solar cell modules are located in close proximity and that a gap is formed between the ends of the main overhanging pieces of the main frame members of adjacent solar cell modules.

This enables water flowing over the surface of the solar cell modules to flow along their main overhanging pieces and down through the gaps formed between their main overhanging pieces.

It is thus possible to prevent water flowing over the surfaces of the solar cell panels from collecting on the surfaces of the solar cell modules and to suppress a reduction in the power generation efficiency of the solar cell modules.

In the solar cell module, while the main frame member or members is or are provided with the main overhanging piece, instead of the provision of such a main overhanging piece, the main retaining upper pieces of the main frame members may have a base end whose upper surface inclines downward toward the outside.

That is, this solar cell module is as follows. Specifically, the solar cell module includes at least a pair of main frame members that retain a pair of opposing main sides of a solar cell panel, and is configured to be installed at an inclination so that one of the main frame members is positioned lower than the other.

In this solar cell module, the main frame members each include a main retaining portion and a main wall portion. Among these, the main retaining portion includes a main retaining wall that runs along a main side of the solar cell panel, and a main retaining upper piece and a main retaining lower piece that project inward from upper and lower ends of the main retaining wall, respectively, and engage and retain an edge portion of the main side of the solar cell panel therebetween. The main wall portion is connected to and extends downward below the main retaining portion.

A feature of this solar cell module is that the main retaining upper piece of at least the one of the main frame members that is positioned lower than the other has a base end whose upper surface inclines downward toward the outside, as described above.

Accordingly, when the solar cell module is installed in place with gradual inclines such as a gently sloping roof, water flowing over the surface of the solar cell module can flow down over the upper surface of the base end of the main retaining upper piece of one of the main frame members that projects at a downward inclination toward the outside.

It is thus possible to prevent water flowing over the surface of the solar cell panel from collecting on the surface of the solar cell module and to suppress a reduction in the power generation efficiency of the solar cell module.

In the solar cell module, the main retaining upper pieces of both of the main frame members may have a base end whose upper surface inclines downward toward the outside. In this case, it is preferable that the solar cell module is installed at a plurality of locations adjacent to one another so that the main frame members of the solar cell modules are located in close proximity and that a gap is formed between the main frame members of adjacent ones of the solar cell modules.

This enables water flowing over the surfaces of the solar cell modules to flow along the main retaining upper pieces of their main frame members and down through the gaps formed between the main retaining upper pieces of their main frame members.

It is thus possible to prevent water flowing over the surfaces of the solar cell panels from collecting on the surfaces of the solar cell modules and to suppress a reduction in the power generation efficiency of the solar cell modules.

Alternatively, each of the solar cell modules as described above may be configured so that the main retaining upper pieces of the main frame members have an inner end whose upper surface inclines downward toward the inside.

This facilitates the movement of water flowing over the surface of the solar cell panel of the solar cell module to the upper surfaces of the main frame members, thus making it easy to guide the water flowing over the surface of the solar cell panel to the main overhanging pieces or to the proximal edges of the main retaining upper pieces.

It is thus possible to prevent water flowing over the surface of the solar cell panel from collecting on the surface of the solar cell module and to suppress a reduction in the power generation efficiency of the solar cell module.

The solar cell module may be configured such that the main frame members are each provided with a main frame side plate that covers a side end face of the main retaining portion of the main frame member and a side end face of the edge portion of the solar cell panel fitted in the main retaining portion.

This enables the solar cell module to be configured so as to retain the solar cell panel with only the main frame members, thus suppressing an increase in the manufacturing cost of the solar cell module.

It is thus possible to manufacture a solar cell module that can prevent water flowing over the surface of the solar cell panel from collecting on the surface of the solar cell module, while reducing the manufacturing cost.

Alternatively, the solar cell module may be configured to include a pair of sub-frame members, instead of using the main frame side plates. The sub-frame members are provided to retain a pair of adjoining sides that adjoin the main sides of the solar cell panel of the solar cell module.

The above sub-frame members each includes a sub-retaining portion and a sub-wall portion. Among these, the sub-retaining portion includes a sub-retaining wall that runs along an adjoining side of the solar cell panel, and an upper sub-retaining piece and a lower sub-retaining piece that project inward from upper and lower ends of the sub-retaining wall, respectively, and engage and retain an edge portion of the adjoining side of the solar cell panel therebetween. The sub-wall portion is connected to and extends downward below the sub-retaining portion.

A feature of the solar cell module is that it includes a sub-overhanging piece. The sub-overhanging piece is included in at least one of the sub-frame members and projects from the upper end of the sub-retaining wall of the sub-retaining portion at a downward inclination toward the outside, and its upper surface communicates with an upper surface of the upper sub-retaining piece.

The inclusion of such a sub-overhanging piece enables the solar cell module, when installed in places with gradual inclines such as a gently sloping roof, to cause water flowing over the surface of the solar cell module to flow down, not only along the main overhanging pieces projecting from the main retaining walls, but also along the sub-overhanging pieces projecting from the sub-retaining walls.

It is thus possible to prevent water flowing over the surface of the solar cell panel from collecting on the surface of the solar cell module and to suppress a reduction in the power generation efficiency of the solar cell module.

In the solar cell module provided with the above sub-frame members, both of the sub-frame members may be provided with the sub-overhanging piece. In this case, it is preferable that the solar cell module is installed at a plurality of locations adjacent to one another so that ends of the sub-overhanging pieces of the sub-frame members of the solar cell modules are located in close proximity and that a gap is formed between the ends of the sub-overhanging pieces of the sub-frame members of adjacent ones of the solar cell modules.

This allows water flowing over the surfaces of the solar cell modules not only to flow down along the main overhanging pieces, but also to flow down along their sub-overhanging piece described above through the gaps formed between their sub-overhanging pieces.

It is thus possible to further enhance the effect of preventing water flowing over the surfaces of the solar cell panels from collecting on the surfaces of the solar cell modules and to suppress a reduction in the power generation efficiency of the solar cell modules.

In the solar cell module, while the sub-frame members are provided with the sub-overhanging pieces, instead of the provision of such sub-overhanging pieces, the upper sub-retaining pieces of the sub-frame members may have a base end whose upper surface inclines downward toward the outside.

That is, this solar cell module is something as follows. Specifically, the solar cell module is installed with a pair of sub-frame members that retain a pair of adjoining sides that adjoin the opposing main sides of a solar cell module.

In this solar cell module, the sub-frame members each include a sub-retaining portion and a sub-wall portion. Among these, the sub-frame member includes a sub-retaining wall that runs along an adjoining side of the solar cell panel, and an upper sub-retaining piece and a lower sub-retaining piece that project inward from upper and lower ends of the sub-retaining wall, respectively, and engage and retain an edge portion of the adjoining side of the solar cell module therebetween. The sub-wall portion is connected to and extends downward below the sub-retaining portion.

A feature of this solar cell module is that the upper sub-retaining piece of at least one of the sub-frame members that is positioned lower than the other has a base end whose upper surface inclines downward toward the outside, as described above.

Thus, when this solar cell module is installed in places with gradual inclines such as a gently sloping roof, water flowing over the surface of the solar cell module can flow downward over the upper surface of the base end of the upper sub-retaining piece of one of the sub-frame members that project at a downward inclination toward the outside.

It is thus possible to prevent water flowing over the surface of the solar cell panel from collecting on the surface of the solar cell module and to suppress a reduction in the power generation efficiency of the solar cell module.

In the solar cell module, the upper sub-retaining pieces of both of the sub-frame members may have a base end whose upper surface inclines downward toward the outside. In this case, it is preferable that the solar cell module is installed at a plurality of locations adjacent to one another so that the sub-frame members of the solar cell modules are located in close proximity and that a gap is formed between the sub-frame members of adjacent ones of the solar cell modules.

This allows water flowing over the surface of the solar cell modules to flow along the upper sub-retaining pieces of their sub-frame members and down through the gaps formed between the upper sub-retaining pieces of their sub-frame members.

It is thus possible to prevent water flowing over the surfaces of the solar cell panels from collecting on the surfaces of the solar cell modules and to suppress a reduction in the power generation efficiency of the solar cell modules.

The solar cell module with the above sub-frame members may be configured so that the upper sub-retaining pieces of the sub-frame members have an inner end whose upper surface inclines downward toward the inside. This facilitates the movement of water flowing over the surface of the solar cell panel of the solar cell module to the upper surfaces of the upper sub-retaining pieces of the sub-frame members, thus making it easy to guide the water flowing over the surface of the solar cell panel to the sub-overhanging pieces or to the proximal edges of the upper sub-retaining pieces.

It is thus possible to prevent water flowing over the surface of the solar cell panel from collecting on the surface of the solar cell module and to suppress a reduction in the power generation efficiency of the solar cell module.

### Effects of the Invention

According to the present invention, in the solar cell module, at least the one of the main frame members that is positioned lower than the other is provided with a main overhanging piece that projects from the upper end of the main retaining wall of the main retaining portion at a downward inclination toward the outside and whose upper surface communicates with the upper surface of the main retaining upper piece. Alternatively, the main retaining upper piece of at least the one of the main frame members that is positioned lower than the other has a base end whose upper surface inclines downward toward the outside.

Thus, when the solar cell module is installed in places with gradual inclines such as a gently sloping roof, water flowing over the surface of the solar cell module can flow down over the main overhanging pieces that project from one of the main frame members at a downward inclination toward the outside, or over the upper surface of the base end of the main retaining upper piece that project at a downward inclination toward the outside.

It is thus possible to prevent water flowing over the surface of the solar cell panel from collecting on the surface of the solar cell module and to suppress a reduction in the power generation efficiency of the solar cell module.

Alternatively, both of the main frame members of the solar cell module may be provided with the above-mentioned main overhanging piece. In this case, a plurality of solar cell module are installed adjacent to one another so that the ends of the main overhanging pieces of the main frame members of the solar cell module are located in close proximity and that a gap is formed between the ends of the main overhanging pieces of the main frame members of adjacent ones of the solar cell modules.

Alternatively, the main retaining upper pieces of both of the main frame members of the solar cell module may have a base end whose upper surface inclines downward toward the outside. In this case, the solar cell module can be installed at a plurality of locations adjacent to one another so that the main frame members of the solar cell modules are located in close proximity and that a gap is formed between the main frame members of adjacent ones of the solar cell modules.

Thus, water flowing over the surfaces of the solar cell modules can flow over their main overhanging pieces and down through the gaps formed between their main overhanging pieces. Or, water flowing over the surfaces of the solar cell modules can flow over the main retaining upper pieces of their main frame members and down through the gaps formed between the main retaining upper pieces of their main frame members.

It is thus possible to prevent water flowing over the surfaces of the solar cell panels from collecting on the surfaces of the solar cell modules and to suppress a reduction in the power generation efficiency of the solar cell modules.

Alternatively, the solar cell module may be configured such that the main retaining upper pieces of the main frame members of the solar cell module have an inner end whose upper surface inclines downward toward the inside.

This facilitates the movement of water flowing over the surface of the solar cell panel of the solar cell module to the upper surfaces of the main retaining upper pieces of the main frame members, thus making it easy to guide the water flowing over the surface of the solar cell panel to the main overhanging pieces or to the proximal edges of the main retaining upper pieces.

It is thus possible to prevent water flowing over the surface of the solar cell panel from collecting on the surface of the solar cell module and to suppress a reduction in the power generation efficiency of the solar cell module.

### BRIEF DESCRIPTION OF DRAWINGS

FIG. 1 is a plan view of a solar cell module according to Embodiment 1.

FIG. 2 is a front view of the solar cell module according to Embodiment 1.

FIG. 3 a right side view of the solar cell module according to Embodiment 1.

FIG. 4 is a perspective view of a corner portion of the solar cell module according to Embodiment 1.

FIG. 5 is an exploded perspective view of the corner portion of the solar cell module according to Embodiment 1.

FIG. 6 is an explanatory drawing illustrating installation of the solar cell module according to Embodiment 1.

FIG. 7 is a cross-sectional view showing another example of a main frame member of the solar cell module according to Embodiment 1.

FIG. 8 is a (first) perspective view showing another example of the corner portion of the solar cell module according to Embodiment 1.

FIG. 9 is a (first) exploded perspective view showing another example of the corner portion of the solar cell module according to Embodiment 1.

FIG. 10 is a (second) perspective view showing still another example of the corner portion of the solar cell module according to Embodiment 1.

FIG. 11 is a (second) exploded perspective view showing still another example of the corner portion of the solar cell module according to Embodiment 1.

FIG. 12 is a plan view of a solar cell module according to Embodiment 2.

FIG. 13 is a front view of the solar cell module according to Embodiment 2.

FIG. 14 is a right side view of the solar cell module according to Embodiment 2.

FIG. 15 is an explanatory drawing illustrating installation of the solar cell module according to Embodiment 2.

FIG. 16 is a plan view of a solar cell module according to Embodiment 3.

FIG. 17 is a front view of the solar cell module according to Embodiment 3.

FIG. 18 is a right side view of the solar cell module according to Embodiment 3.

FIG. 19 is a perspective view of a corner portion of the solar cell module according to Embodiment 3.

FIG. 20 is an exploded perspective view of the corner portion of the solar cell module according to Embodiment 3.

FIG. 21 is a (first) perspective view showing another example of the corner portion of the solar cell module according to Embodiment 3.

FIG. 22 is a (first) exploded perspective view showing another example of the corner portion of the solar cell module according to Embodiment 3.

FIG. 23 is a (second) perspective view showing still another example of the corner portion of the solar cell module according to Embodiment 3.

FIG. 24 is a (second) exploded perspective view showing still another example of the corner portion of the solar cell module according to Embodiment 3.

FIG. 25 is a cross-sectional view showing another example of a sub-frame member of the solar cell module according to Embodiment 3.

FIG. 26 is a plan view of a solar cell module according to Embodiment 4.

FIG. 27 is a front view of the solar cell module according to Embodiment 4.

FIG. 28 is a right side view of the solar cell module according to Embodiment 4.

FIG. 29 is a perspective view of a corner portion of the solar cell module according to Embodiment 4.

FIG. 30 is an exploded perspective view of the corner portion of the solar cell module according to Embodiment 4.

FIG. 31 is a perspective view showing another example of the corner portion of the solar cell module according to Embodiment 4.

FIG. 32 is an exploded perspective view showing another example of the corner portion of the solar cell module according to Embodiment 4.

FIG. 33 is a plan view of a solar cell module according to Embodiment 5.

FIG. 34 is a a front view of the solar cell module according to Embodiment 5.

FIG. 35 is a right side view of the solar cell module according to Embodiment 5.

FIG. 36 is a (first) explanatory drawing showing another example configuration of the main retaining portion according to the embodiments.

FIG. 37 is a (second) explanatory drawing showing still another example configuration of the main retaining portion according to the embodiments.

FIG. 38 is a (third) explanatory drawing showing still another example configuration of the main retaining portion according to the embodiments.

FIG. 39 is a (fourth) explanatory drawing showing still another example configuration of the main retaining portion according to the embodiments.

FIG. 40 is a (fifth) explanatory drawing showing still another example configuration of the main retaining portion according to the embodiments.

FIG. 41 is a (sixth) explanatory drawing showing still another example configuration of the main retaining portion according to the embodiments.

### DESCRIPTION OF REFERENCE NUMERALS

1a Solar cell module

1b Solar cell module

1c Solar cell module

2a Solar cell module

3a Solar cell module

3b Solar cell module

3c Solar cell module

4a Solar cell module

4b Solar cell module

5a Solar cell module

6 Horizontal surface

7 Inclination angle

8 Installation surface

9 Solar cell panel

11a Main frame member

11b Main frame member

11c Main frame member

11d Main frame member

12a Sub-frame member

12b Sub-frame member

12c Sub-frame member

12d Sub-frame member

12e Sub-frame member

13 Contact wall

14 Hook piece

20a Main retaining portion

20b Main retaining portion

20c Main retaining portion

20d Main retaining portion

20e Main retaining portion

20f Main retaining portion

20g Main retaining portion

20h Main retaining portion

21 Main retaining wall

22 Main retaining upper piece

22a Upper piece end face

23 Main retaining lower piece

23a Screw locking piece

24 Main overhanging piece

24a Main overhanging piece

24b Main overhanging piece

30a Main wall portion

30b Main wall portion

30c Main wall portion

31 Main outer wall

32 Main bottom piece

32a Screw locking piece

33 Main inner wall

40a Sub-retaining portion

40b Sub-retaining portion

41 Sub-retaining wall

42 Upper sub-retaining piece

42a Upper piece end face

43 Lower sub-retaining piece

44 Sub-overhanging piece

50a Sub-wall portion

50b Sub-wall portion

50c Sub-wall portion

51 Sub-outer wall

52 Sub-bottom piece

53 Sub-inner wall

54 Screw hole

61 Main frame side plate

### MODE FOR CARRYING OUT THE INVENTION

Next, embodiments of a solar cell module according to the present invention will be described with reference to the drawings. In the description of the embodiments of the present invention, five embodiments, namely Embodiments 1 to 5, of the solar cell module are described.

### Embodiment 1

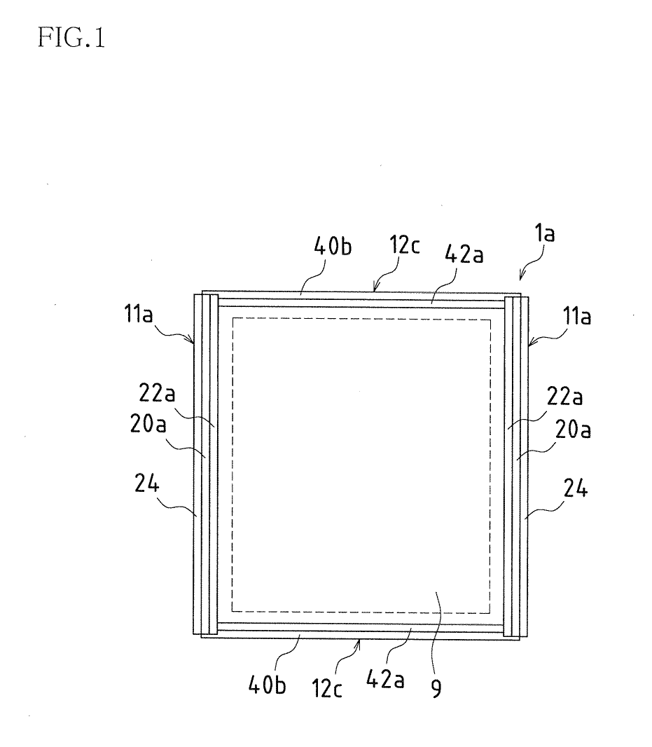

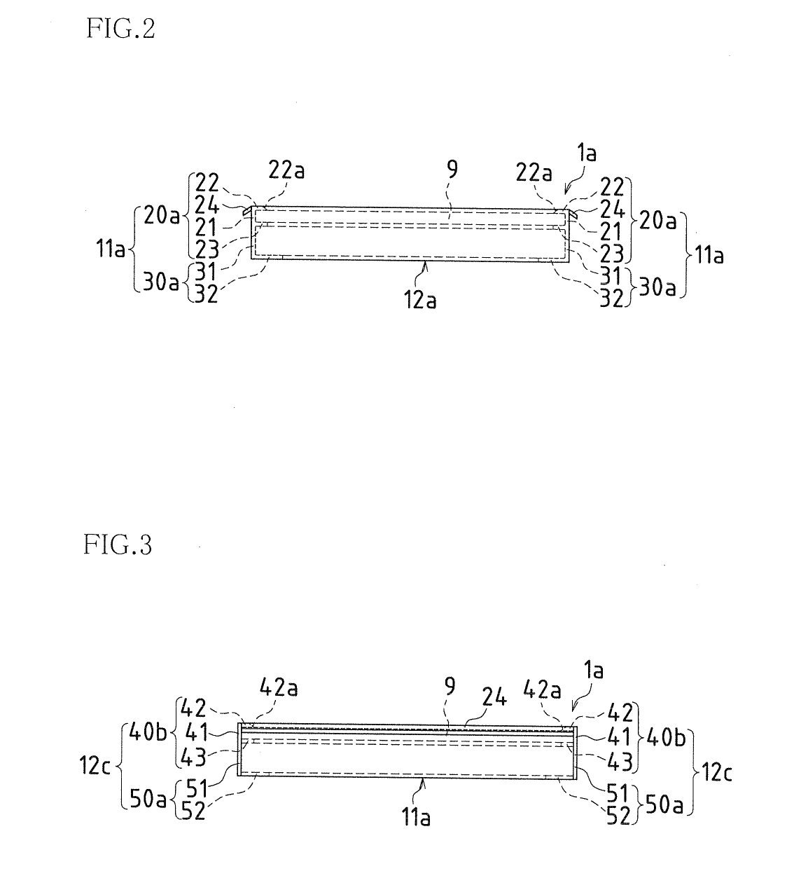

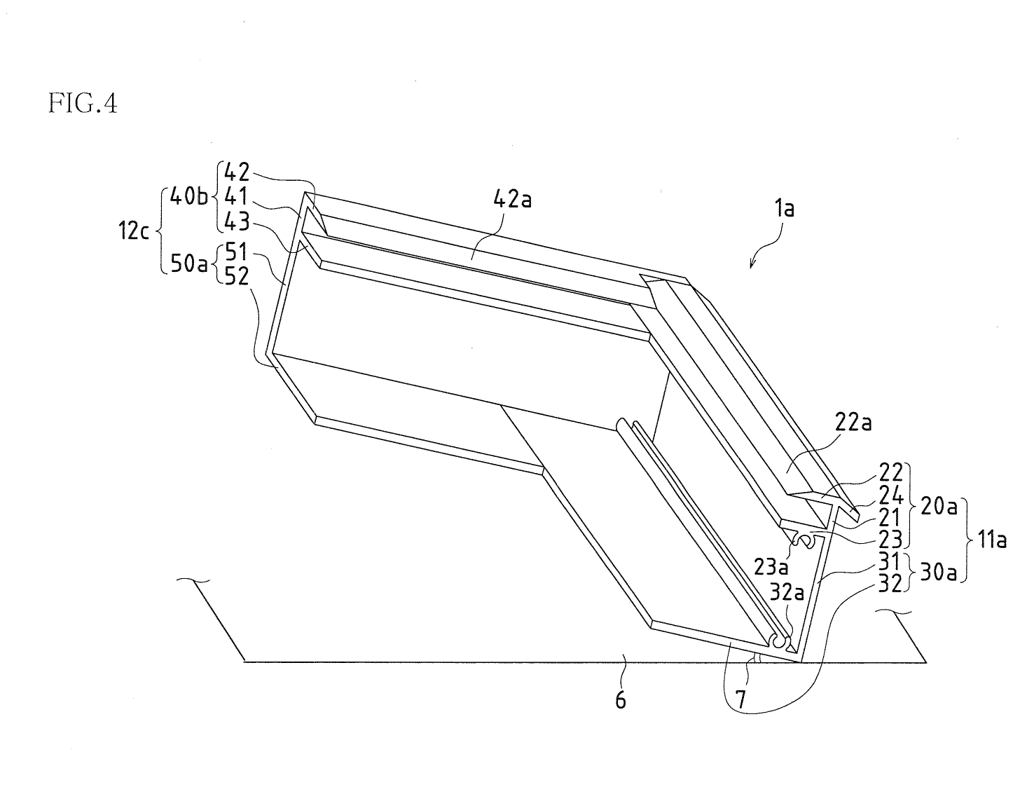

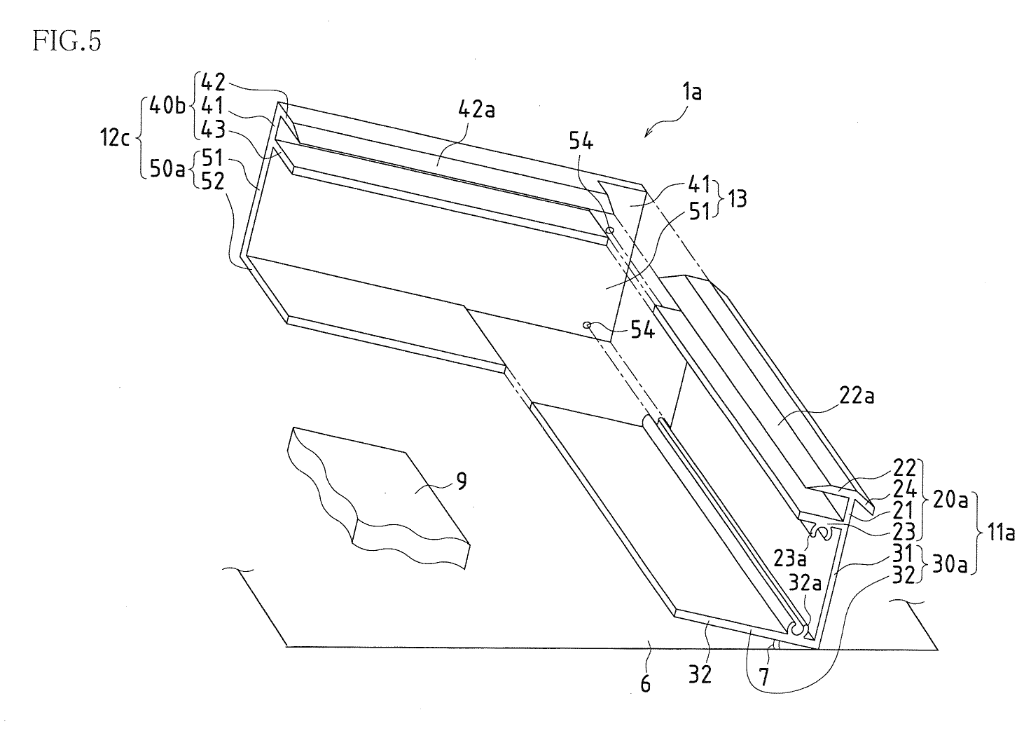

FIG. 1 is a plan view of a solar cell module 1a according to Embodiment 1, FIG. 2 is a front view thereof, FIG. 3 is a right side view thereof, FIG. 4 is a perspective view of a corner portion thereof, and FIG. 5 is an exploded perspective view of the corner portion. Note that a solar cell panel 9 is omitted in FIG, 4. FIGS. 4 and 5 show that the solar cell module 1a is inclined at an inclination angle 7 relative to a horizontal surface 6.

Specifically, the solar cell module 1a according to Embodiment 1 is installed at the inclination angle 7 at which water flow is stopped by the surface tension, and more specifically, although depending on the surface condition, at a place such as a roof that is inclined at 0 to 45 degrees, desirably 0 to 30 degrees, and along the inclination of such a roof so that one of a pair of main frame members 11a, which will be described later, is positioned lower than the other.

The solar cell module 1a according to Embodiment 1 has the following structure. Referring to FIGS. 1 to 5, the solar cell panel 9 has a rectangular shape with long sides (corresponding to the aforementioned main sides) and short sides (corresponding to the aforementioned adjoining sides of the main sides) and is held and surrounded by the pair of main frame members 11a that retain the long sides of the solar cell panel 9 and a pair of sub-frame members 12c that retain the short sides, which are adjoining sides of the main sides.

The main frame members 11a each include a main retaining portion 20a and a main wall portion 30a. The main retaining portion 20a includes a main retaining wall 21, a main retaining upper piece 22, a main retaining lower piece 23, and a main overhanging piece 24. The main retaining wall 21 is formed along a long side of the solar cell panel 9. The main retaining upper piece 22 and the main retaining lower piece 23 are formed projecting from upper and lower ends of the main retaining wall 21, respectively, for example with substantially the same length and in parallel with each other.

An edge portion of the long side of the solar cell panel 9 is fitted and held in a portion formed by the main retaining wall 21, the main retaining upper piece 22, and the main retaining lower piece 23, the portion having a U-shaped cross section, for example.

The main overhanging piece 24 projects from the upper end of the main retaining wall 21 of the main retaining portion 20a with a linearly downward inclination toward the outside. The main overhanging piece 24 is formed so that the upper surface of the main overhanging piece 24 communicates with the upper surface of the main retaining upper piece 22, and it is preferable that the angle formed by the upper surface of the main overhanging piece 24 and the upper surface of the main retaining upper piece 22 is an angle at which gravity surpasses surface tension when water flow is stopped by surface tension in the absence of the main overhanging piece 24. More specifically, although depending on the surface condition, the angle is preferably 1 to 60 degrees when the solar cell module is placed on a variety of roofs from flat and folded-plate roofs with relatively small inclination angles to house roofs with large inclination angles, and preferably 5 to 30 degrees when the solar cell module is placed in places with gradual inclines such as gently sloping roofs.

Moreover, an upper piece end face 22a, which is the upper surface of an inner end portion of the main retaining upper piece 22 of the main retaining portion 20a, inclines downward toward the inside. Furthermore, a screw locking piece 23a is provided on the underside of the main retaining lower piece 23.

The main wall portion 30a is connected to and extends downward below the main retaining portion 20a, and includes a main outer wall 31 and a main bottom piece 32. The main outer wall 31 is formed connected to the main retaining wall 21 of the main retaining portion 20a. The main bottom piece 32 projects, for example, inwardly in parallel from the lower end of the main outer wall 31. A screw locking piece 32a is provided at a position near the main outer wall 31 on the upper surface of the main bottom piece 32.

In the present embodiment, while the main wall portion 30a includes the main outer wall 31 and the main bottom piece 32, the configuration of the main wall portion 30a is not limited thereto and may in some cases have other configurations different from that described above, depending on the form of installation of the module and the method of fixation, for example.

The sub-frame members 12c constituting the solar cell module 1a each include a sub-retaining portion 40b and a sub-wall portion 50a. The sub-retaining portion 40b includes a sub-retaining wall 41, an upper sub-retaining piece 42, and a lower sub-retaining piece 43. The sub-retaining wall 41 is formed along a short side of the solar cell panel 9. The upper sub-retaining piece 42 and the lower sub-retaining piece 43 project from upper and lower ends of the sub-retaining wall 41, respectively, for example with substantially the same length and in parallel with each other.

An edge portion of the short side of the solar cell panel 9 is fitted and held in a portion formed by the sub-retaining wall 41, the upper sub-retaining piece 42, and the lower sub-retaining piece 43, the portion having a U-shaped cross section. An upper piece end face 42a, which is the upper surface of an inner end portion of the main retaining upper piece 42 of the sub-retaining portion 40b, inclines downward toward the inside.

The sub-wall portion 50a includes a sub-outer wall 51 and a sub-bottom piece 52. As shown in FIG. 5, the sub-frame members 12c each have at both ends a contact wall 13 that is formed by a sub-retaining wall 41 and a sub-outer wall 51, and both ends of the sub-bottom pieces 52 are cut off to form notch portions.

As shown in FIG. 5, the solar cell module 1a is formed by bringing the side end faces of the main frame members 11a into contact with the contact walls 13 of the sub-frame members 12c, as well as fitting the main bottom pieces 32 of the frame members 11a into the notch portions of the sub-bottom pieces 52 and coupling the screw locking pieces 23a and 32a into screw holes 54 of the contact walls 13 with screws.

As the method for coupling the main frame members 11a and the sub-frame members 12c in the solar cell module 1a, other coupling methods different from the above may be used.

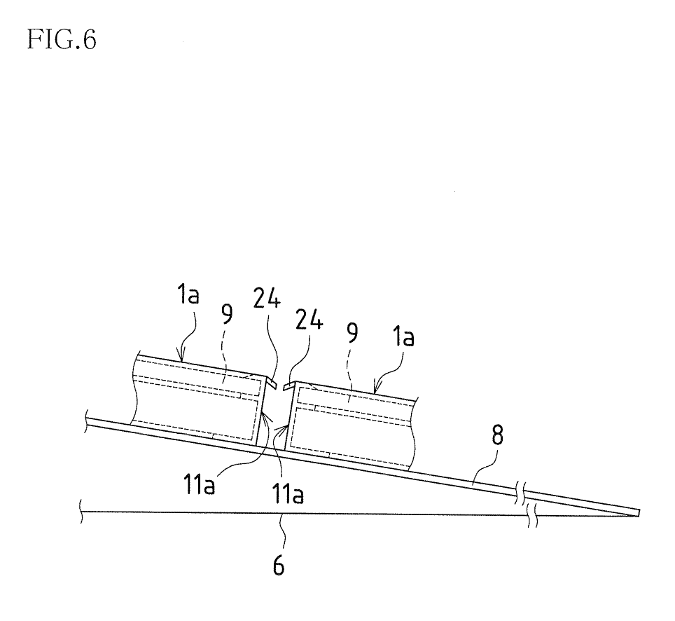

FIG. 6 illustrates the case where multiple solar cell modules 1a as described above are installed so that their long sides are adjacent one below another in a slanting direction. In this case, the solar cell modules 1a are each installed on an installation surface 8, such as a gently sloping roof, so that one of the pair of main frame members 11a is positioned lower than the other.

Also, the solar cell modules 1a are installed such that the ends of the main overhanging pieces 24 of the main frame members 11a of the adjacent solar cell modules 1a are located in close proximity to each other. Still further, the solar cell modules 1a are installed so that a gap is formed between the ends of the main overhanging pieces 24 of the main frame members 11a of the adjacent solar cell modules 1a.

According to the solar cell module 1a described above, since the solar cell module 1a is provided with the main overhanging pieces 24, in cases where the solar cell module 1a is installed in places with gradual inclines such as a gently sloping roof, water flowing over the surface of the solar cell module 1a can flow down over the main overhanging piece 24 of the main retaining portion 20a of one of the main frame members 11a that is positioned lower than the other.

Moreover, referring to the solar cell modules 1a that are installed adjacent one below another in a slanting direction, a gap is formed between the ends of the main overhanging pieces 24 of the main retaining portions 20a of the main frame members 11a. Thus, water flowing over the surfaces of the solar cell modules 1a can flow over the main overhanging pieces 24 of both of the solar cell modules and down through the gap formed between those main overhanging pieces 24.

Still more, the upper piece end face 22a of the main retaining upper piece 22 of the main retaining portion 20a of the main frame member 11a inclines downward toward the inside. This facilitates movement of water that flows on the surface of the solar cell panel 9 of the solar cell module 1a, to the upper surfaces of the main retaining upper pieces 22 of the main retaining portions 20a of the main frame members 11a, thus making it easy to guide the water flowing over the surface of the solar cell panel 9 to the main overhanging pieces 24.

It is thus possible to prevent the water flowing over the surface of the solar cell panel 9 from collecting on the surface of the solar cell module 1a and to suppress a reduction in the power generation efficiency of the solar cell module 1a.

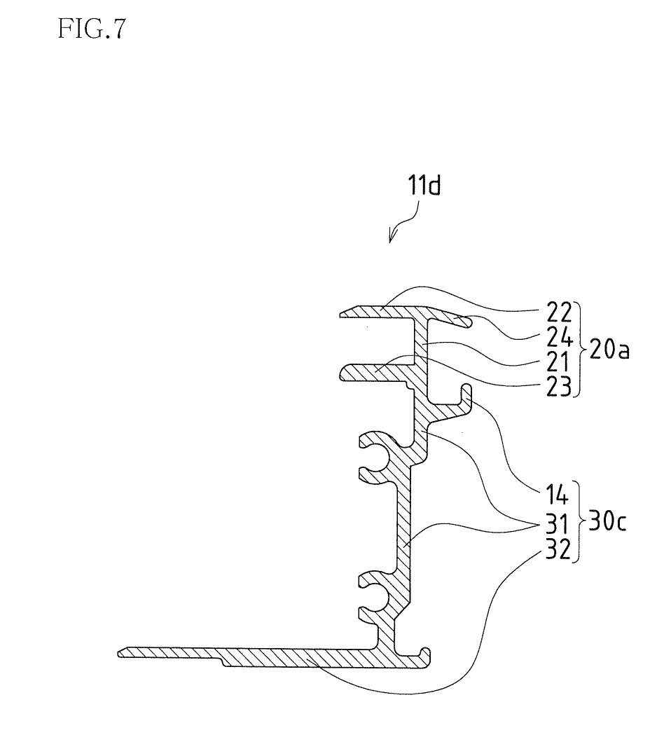

While the solar cell module 1a uses the main frame members 11a, it may use main frame members 11d having a cross-section as shown in FIG. 7, instead of using the main frame members 11a. The main frame members 11d each include a main retaining portion 20a and a main wall portion 30c. The main frame members 11d each also include a hook piece 14 that projects from a main outer wall 31 of a main wall portion 30c and whose end is directed upward toward the outside.

By the use of the main frame members 11d provided with the hook pieces 14, in cases where multiple solar cell modules 1a are installed adjacent to one another, it is possible to fix the hook pieces 14 of the adjacent solar cell modules 1a with a fastening fixture for installation or the like with their outer faces in a face-to-face orientation, which eases the formation of the aforementioned gap between the main overhanging pieces 24.

In this case, the outer faces of the facing hook pieces 14 may be brought to butt against each other by setting in advance the amount of projection of the main overhanging pieces 24 from the main retaining walls 21 smaller than the amount of projection of the hook pieces 14 from the main outer walls 31. Alternatively, a gap between the main overhanging pieces 24 may be formed by setting the amount of projection of the main overhanging pieces 24 from the main retaining walls 21 equal to the amount of projection of the hook pieces 14 from the main outer walls 31 and interposing a fastening fixture between the outer faces of the opposing hook pieces 14.

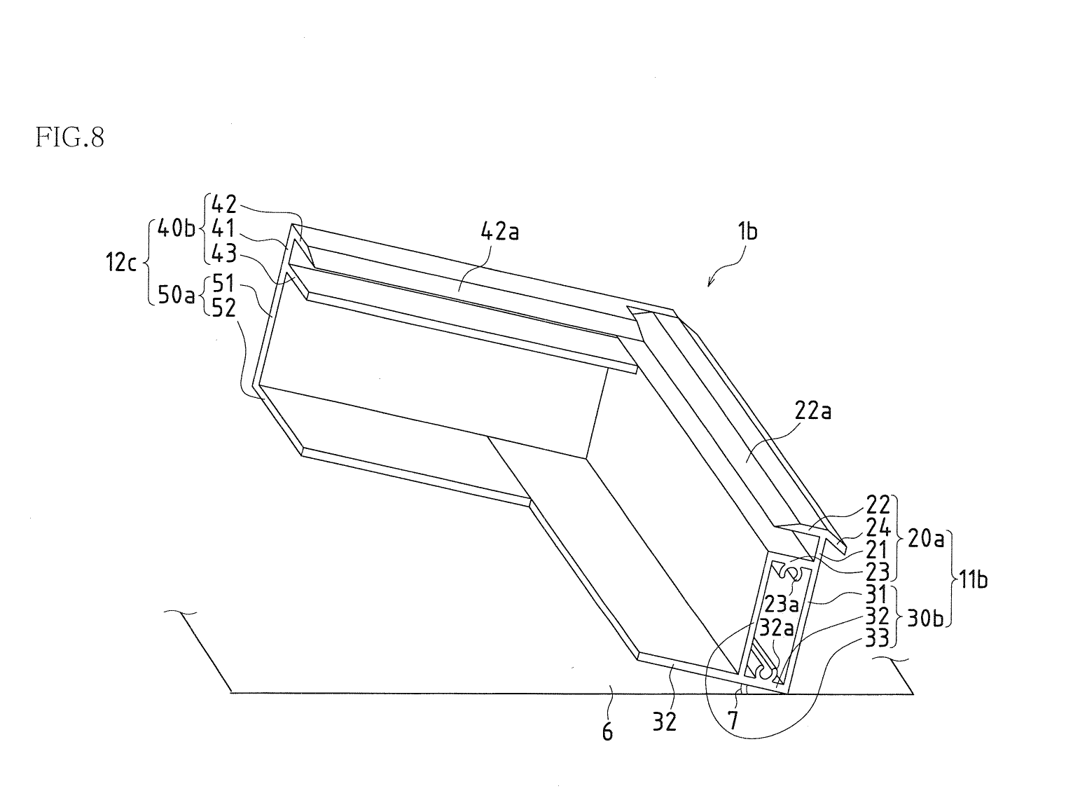

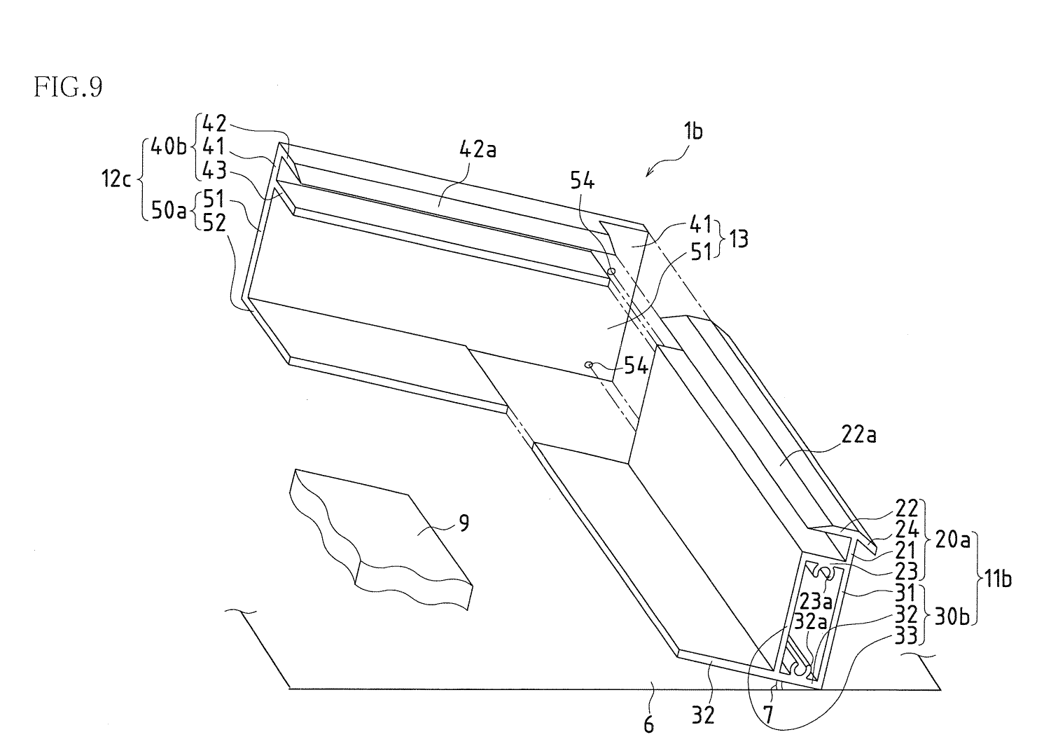

As an alternative, instead of using the main frame members 11a of the solar cell module 1a, a solar cell module 1b that uses main frame members 11b as shown in FIGS. 8 and 9 may be configured. Here, FIG. 8 is a perspective view of a corner portion of the solar cell module 1b, and FIG. 9 is an exploded perspective view of the corner portion of the solar cell module 1b.

The main frame members 11b of the solar cell module 1b differ from the main frame members 11a of the solar cell module 1a in that, while the main wall portions 30a of the main frame members 11a each include the main outer wall 31 and the main bottom piece 32, main wall portions 30b of the main frame members 11b each include a main outer wall 31, a main bottom piece 32, and a main inner wall 33. In other respects, the main frame members 11b are the same as the main frame members 11a.

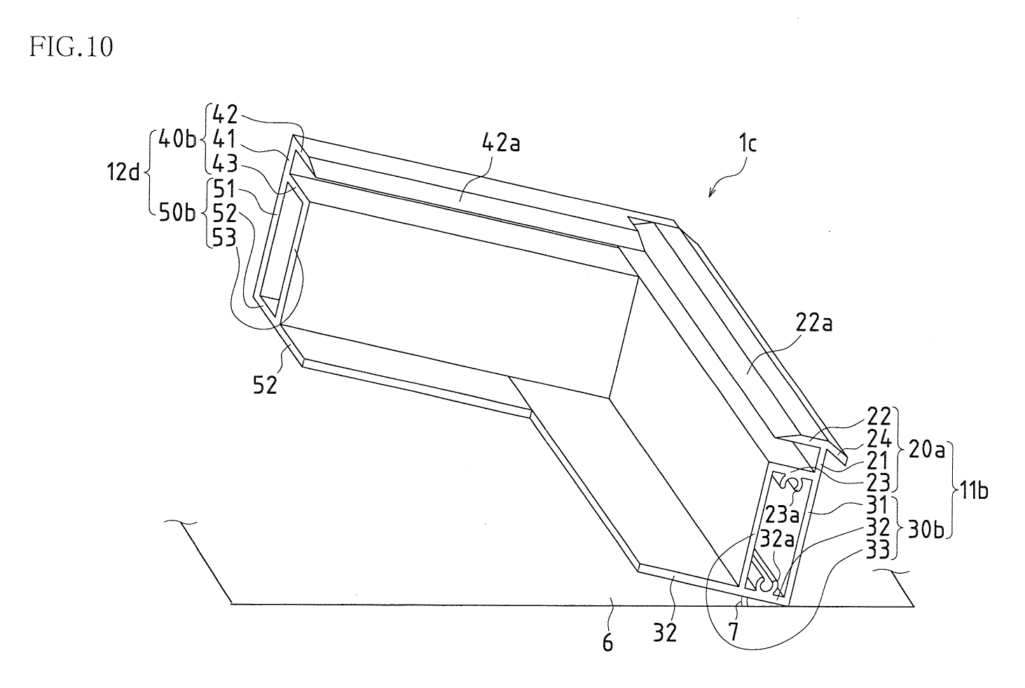

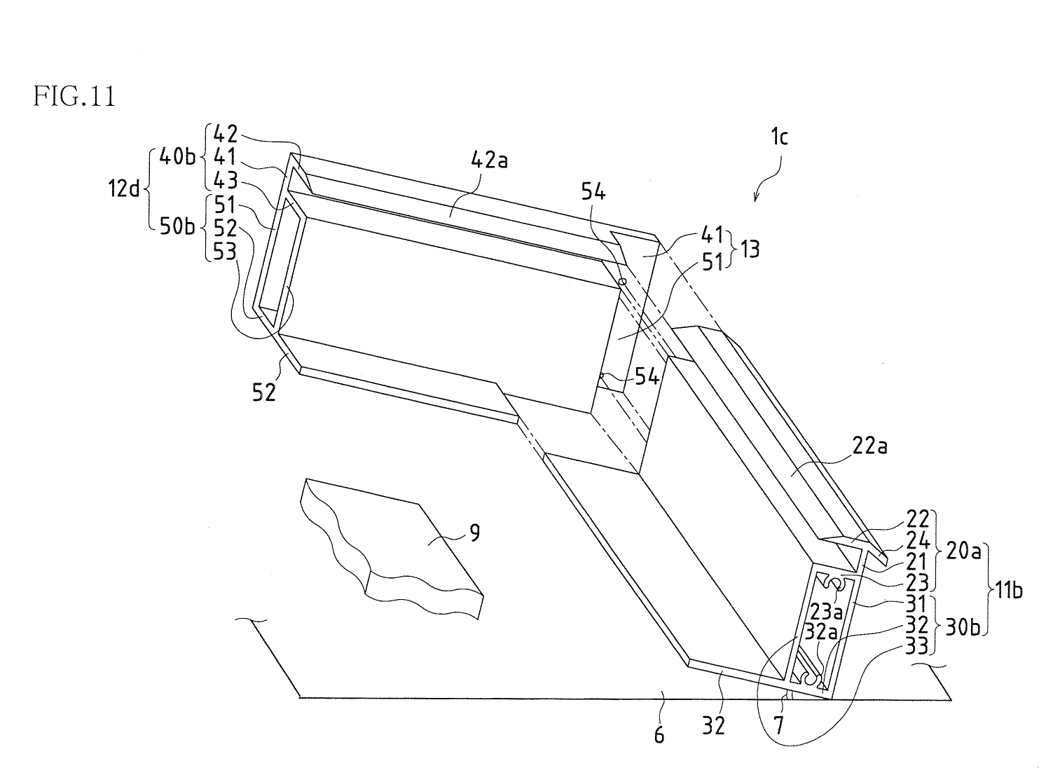

As still another alternative, instead of using the sub-frame members 12c of the solar cell module 1b, a solar cell module 1c that uses sub-frame members 12d as shown in FIGS. 10 and 11 may be configured. Here, FIG. 10 is a perspective view of a corner portion of the solar cell module 1c, and FIG. 11 is an exploded perspective view of the corner portion of the solar cell module 1c.

The sub-frame members 12d of the solar cell module 1c differ from the sub-frame members 12c of the solar cell module 1b in that, while the sub-wall portions 50a of the sub-frame members 12c each include the sub-outer wall 51 and the sub-bottom piece 52, sub-wall portions 50b of the sub-frame members 12d each include a sub-outer wall 51, a sub-bottom piece 52, and a sub-inner wall 53. In other respects, the sub-frame members 12d are the same as the sub-frame members 12c.

### Embodiment 2

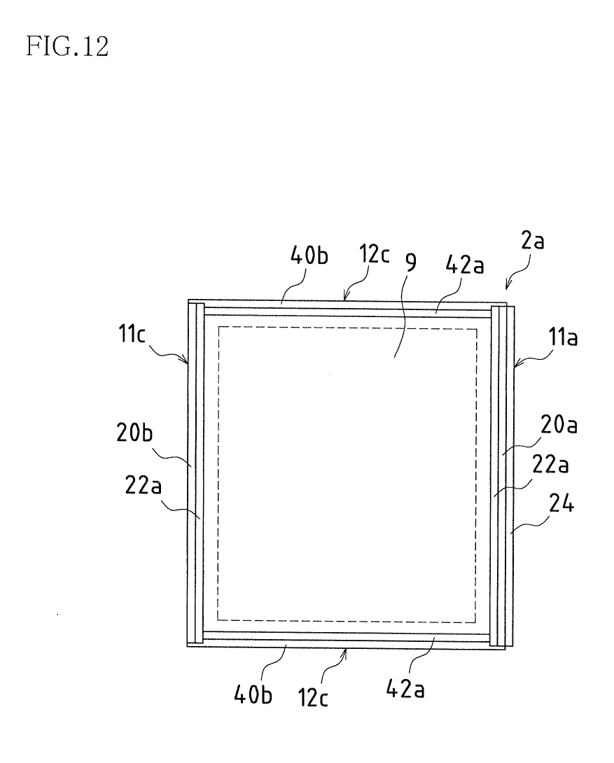

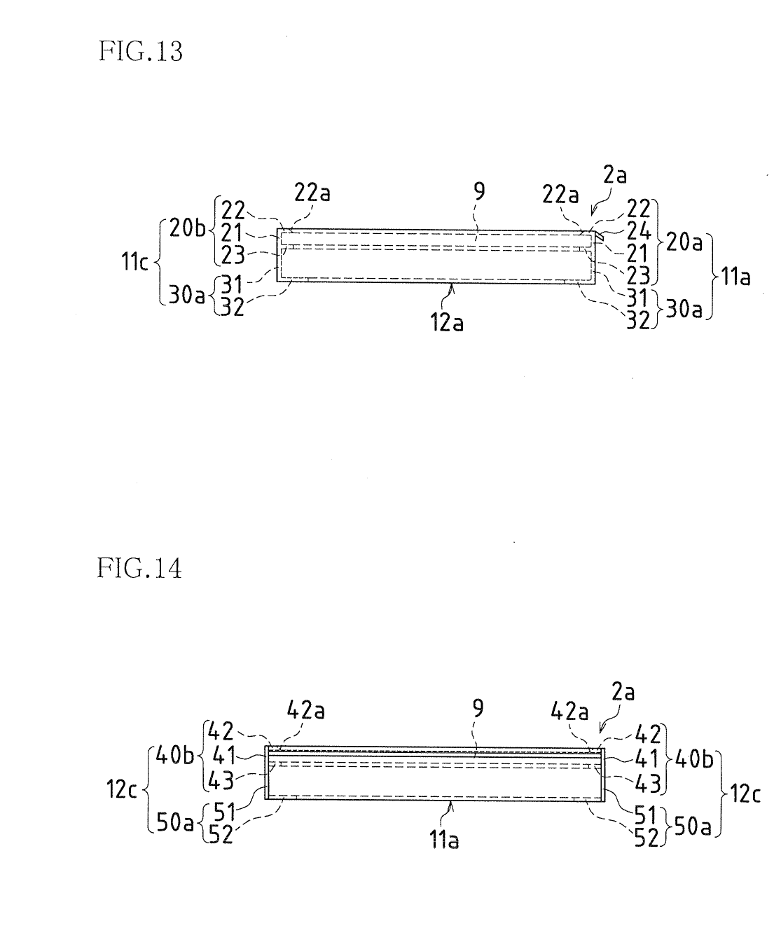

A solar cell module 2a according to Embodiment 2 is a partial modification of the aforementioned solar cell module 1a according to Embodiment 1. FIG. 12 is a plan view of the solar cell module 2a according to Embodiment 2, and FIG. 13 is a front view thereof, and FIG. 14 is a right side view thereof.

The solar cell module 2a according to Embodiment 2 differs from the solar cell module 1a according to Embodiment 1 in that, while in the solar cell module 1a according to Embodiment 1, the main overhanging pieces 24 are formed on the main retaining portions 20a of both of the pair of main frame members 11a, a main overhanging piece 24 is formed on only a main retaining portion 20a of a main frame member 11a of a pair of main frame members 11a and 11c in the solar cell module 2a according to Embodiment 2. In other respects, the solar cell module 2a is the same as the solar cell module 1a according to Embodiment 1.

Specifically, the main frame member 11c includes a main retaining portion 20b and a main wall portion 30a, and the main retaining portion 20b includes a main retaining wall 21, a main retaining upper piece 22, and a main retaining lower piece 23 and does not include a main overhanging piece 24.

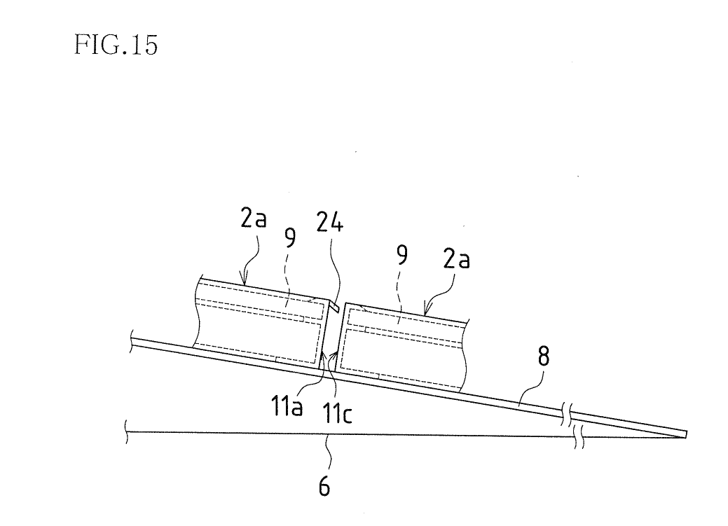

FIG. 15 illustrates the case where multiple solar cell modules 2a as described above are installed adjacent one below another in a slanting direction. In this case, as in the case of the solar cell modules 1a, the solar cell modules 2a are installed on an installation surface 8 such as a gently sloping roof. At this time, the solar cell modules are installed so that the main frame members 11a of the pairs of main frame members 11a and 11c are positioned lower than the other.

The installation is also arranged so that the end of the main overhanging piece 24 of the main frame member 11a of one solar cell module 2a is located in close proximity to the main frame member 11c of the adjacent solar cell module 2a. Still more, the solar cell modules are installed so that a gap is formed between the end of the main overhanging piece 24 of the main frame member 11a of one solar cell module 2a and the main frame member 11c of the adjacent solar cell module 2a.

The solar cell module 2a according to Embodiment 2 can also bring about almost similar functions and effects to those of the aforementioned solar cell module 1a according to Embodiment 1. In addition, substantially the same various measures as those described with the solar cell module 1a according to Embodiment 1 can also be carried out on the solar cell module 2a according to Embodiment 2.

### Embodiment 3

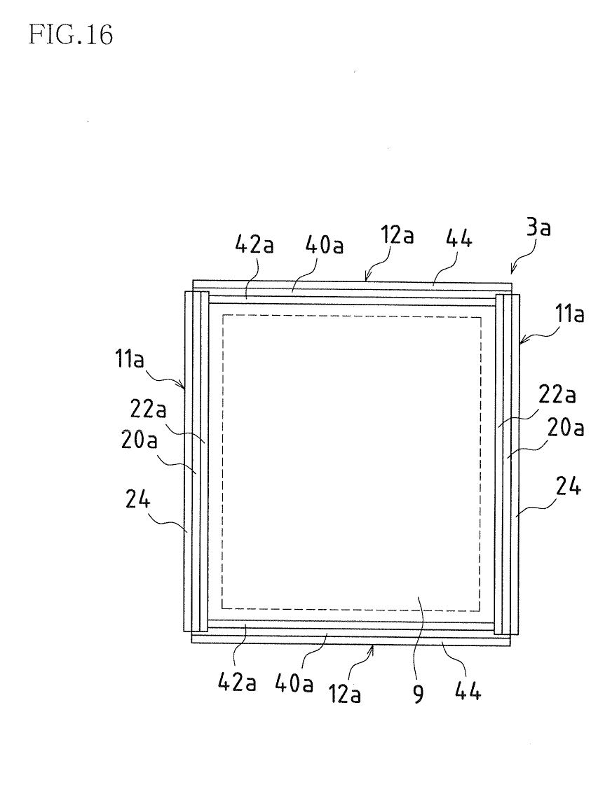

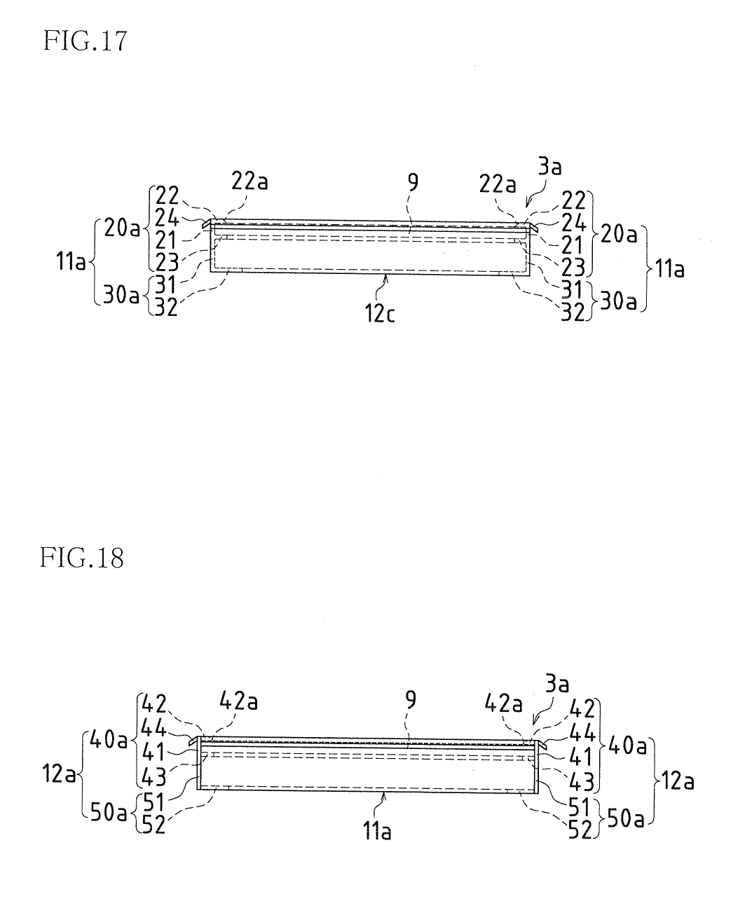

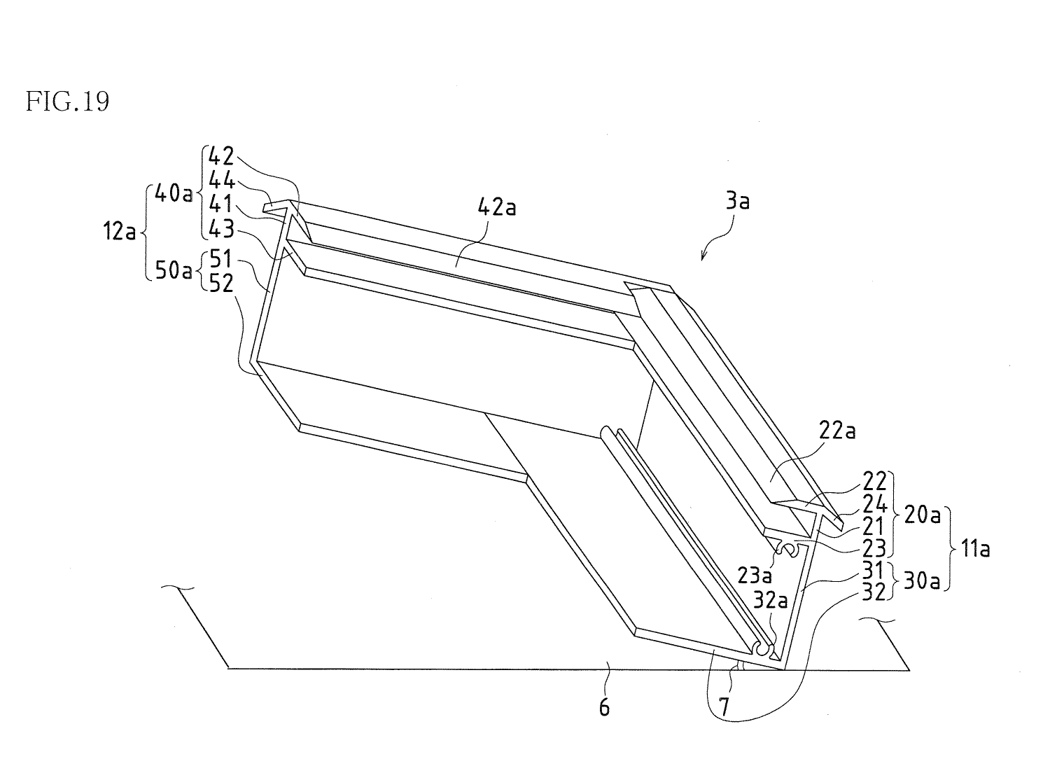

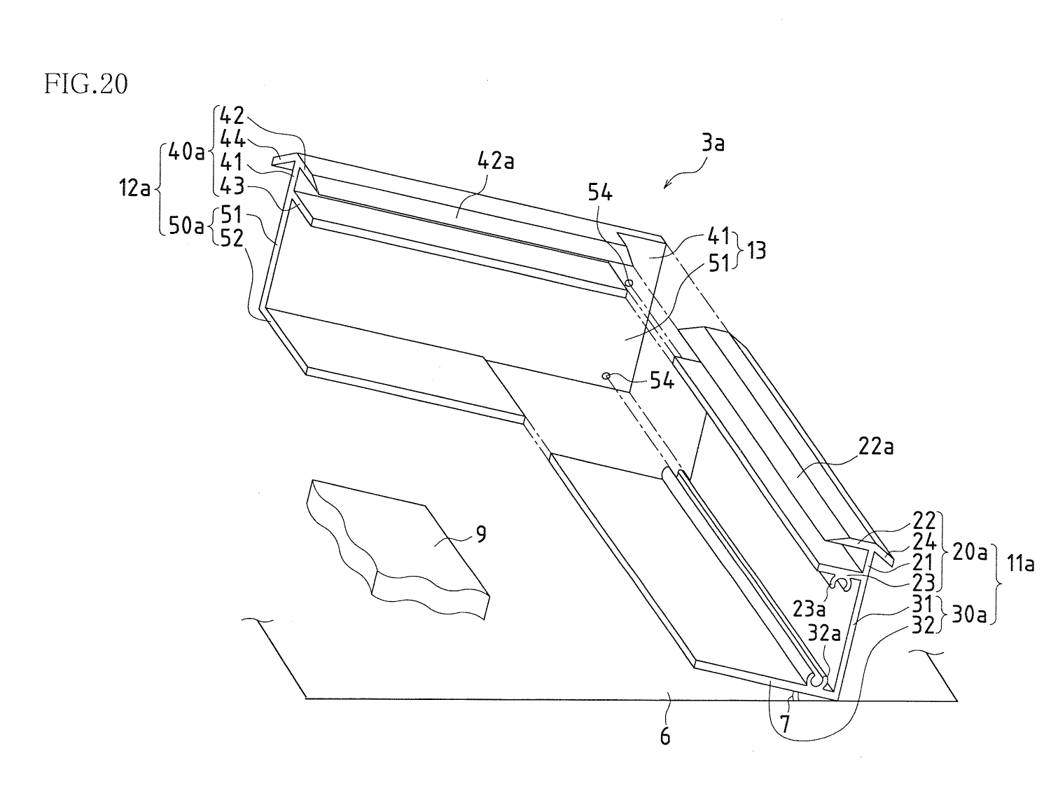

A solar cell module 3a according to Embodiment 3 is a partial modification of the aforementioned solar cell module 1a according to Embodiment 1. FIG. 16 is a plan view of the solar cell module 3a according to Embodiment 3, FIG. 17 is a front view thereof, FIG. 18 is a right side view thereof, FIG. 19 is a perspective view of a corner portion thereof, and FIG. 20 is an exploded perspective view of the corner portion. Note that a solar cell panel 9 is omitted in FIG. 19. FIGS. 19 and 20 show that the solar cell module 3a is inclined at an inclination angle 7 relative to a horizontal surface 6.

Specifically, like the solar cell module 1a according to Embodiment 1, the solar cell module 3a according to Embodiment 3 is installed at the inclination angle 7 at which water flow is stopped by surface tension, and more specifically, although depending on the surface condition, at a place such as a roof that is inclined at an angle of 0 to 45 degrees, preferably 0 to 30 degrees, and along the inclination of such a roof so that one of a pair of main frame members 11a is positioned lower than the other.

More specifically, like the solar cell module 1a according to Embodiment 1, the solar cell module 3a according to Embodiment 3 is installed at a place such as a gently sloping roof with the inclination angle 7 of approximately 3 to 10 degrees and along the inclination of such a roof so that one of the pair of main frame members 11a is positioned lower than the other.

The solar cell module 3a according to Embodiment 3 differs from the solar cell module 1a according to Embodiment 1 in that sub-frame members 12a are used instead of the sub-frame members 12c of the solar cell module 1a according to Embodiment 1. In other respects, the solar cell module 3a is the same as the solar cell module 1a.

The sub-frame members 12a of the solar cell module 3a differ from the sub-frame members 12c of the solar cell module 1a in that while the sub-retaining portions 40b of the sub-frame members 12c are not provided with sub-overhanging pieces, sub-retaining portions 40a of the sub-frame members 12a are provided with sub-overhanging pieces 44. The sub-overhanging pieces 44 are of the same shape as the main overhanging pieces 24 of the main frame members 11a.

According to the solar cell module 3a, not only are the main retaining portions 20a of the main frame members 11a provided with the main overhanging pieces 24, but also the sub-retaining portions 40a of the sub-frame members 12d are provided with the sub-overhanging pieces 44. Thus, in cases where the solar cell module 3a is installed in places with gradual inclines such as a gently sloping roof, water flowing over the surface of the solar cell module 3a can flow downward over, not only the main overhanging pieces 24 projecting from the main retaining portions 20a of the main frame members 11a, but also the sub-overhanging pieces 44 projecting from the sub-retaining portions 40a of the sub-frame members 12d. In addition, the solar cell module 3a has almost similar functions and effects to those of the solar cell module 1a according to Embodiment 1.

It is thus possible to prevent water flowing over the surface of the solar cell panel 9 from collecting on the surface of the solar cell module 3a and to suppress a reduction in the power generation efficiency of the solar cell module 3a.

Moreover, in addition to measures as described below, substantially the same various measures as those described with the aforementioned solar cell module 1a according to Embodiment 1 can also be carried out on the solar cell module 3a.

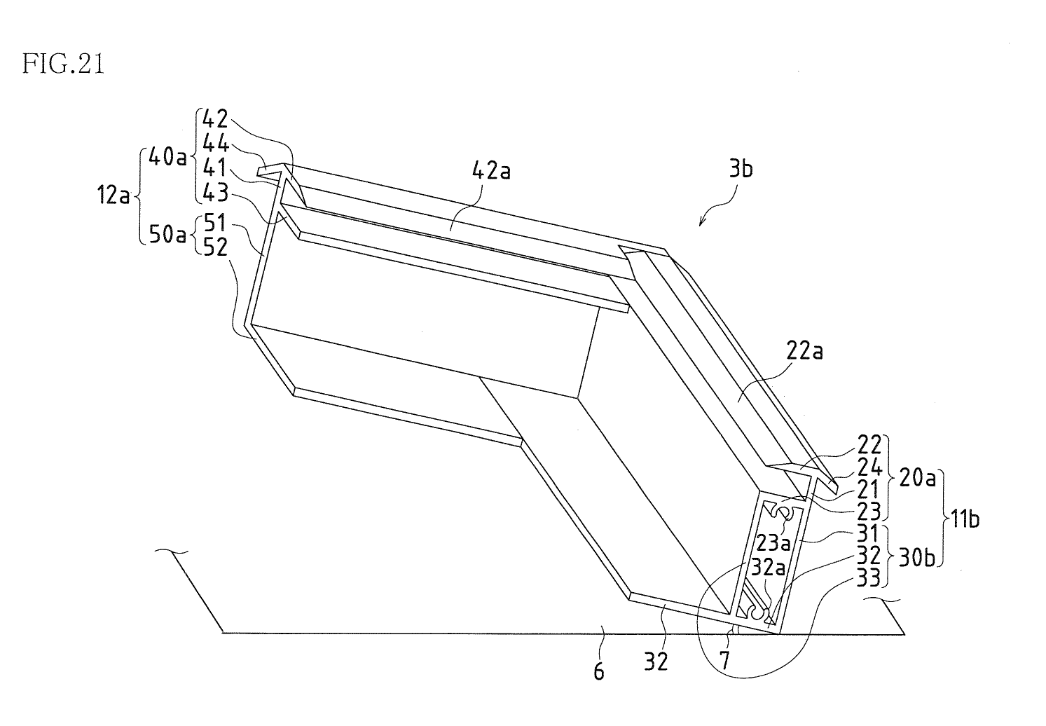

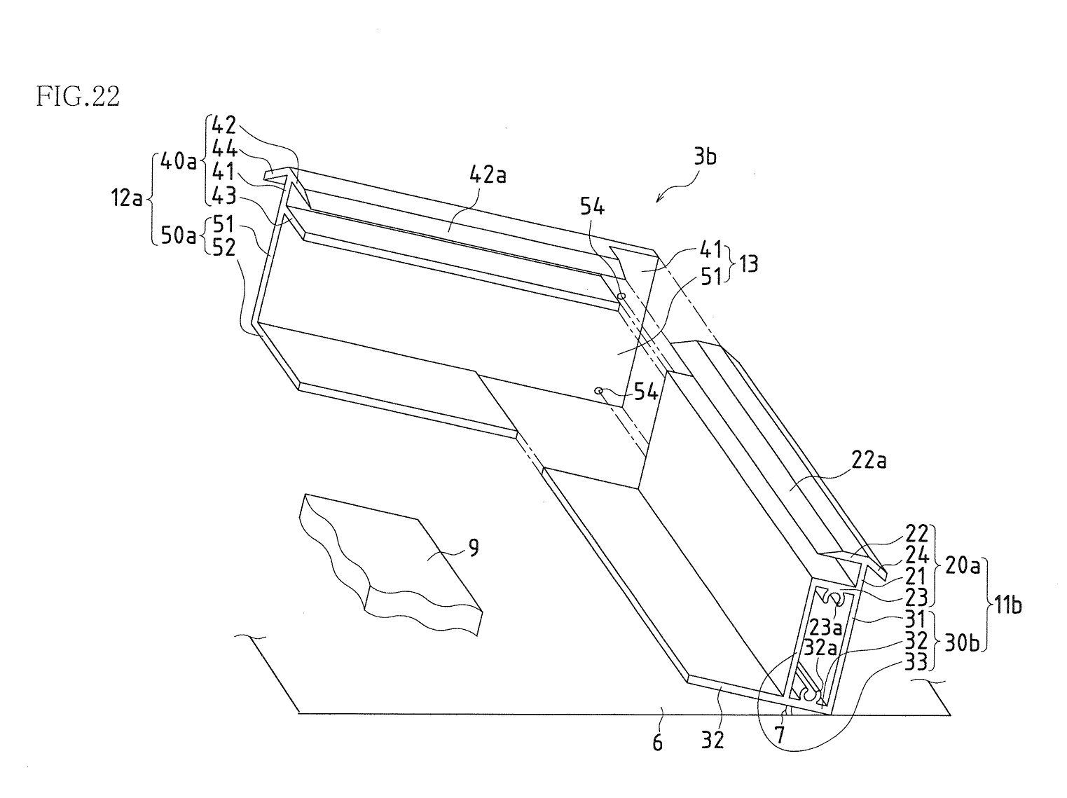

Instead of using the main frame members 11a of the above-described solar cell module 3a, a solar cell module 3b that uses main frame members 11b as shown in FIGS. 21 and 22 may be configured. Here, FIG. 21 is a perspective view of a corner portion of the solar cell module 3b, and FIG. 22 is an exploded perspective view of the corner portion of the solar cell module 3b.

The main frame members 11b of the solar cell module 3b differ from the main frame members 11a of the solar cell module 3a in that while the main wall portions 30a of the main frame members 11a each include the main outer wall 31 and the main bottom piece 32, main wall portions 30b of the main frame members 11b each include a main outer wall 31, a main bottom piece 32, and a main inner wall 33. In other respects, the main frame members 11b are the same as the main frame members 11a.

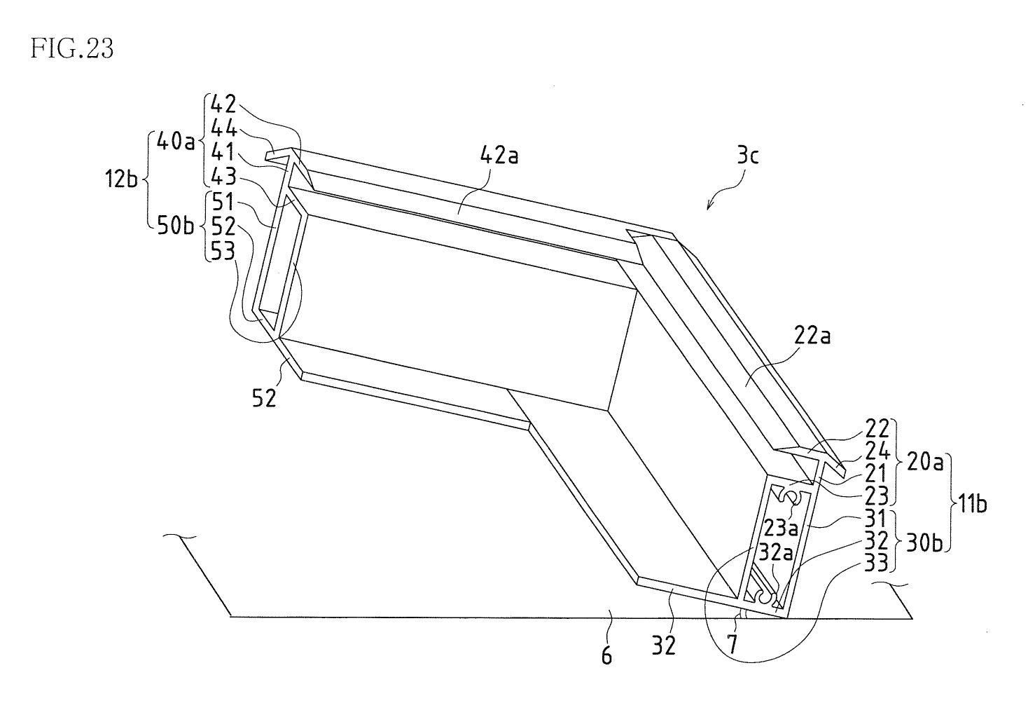

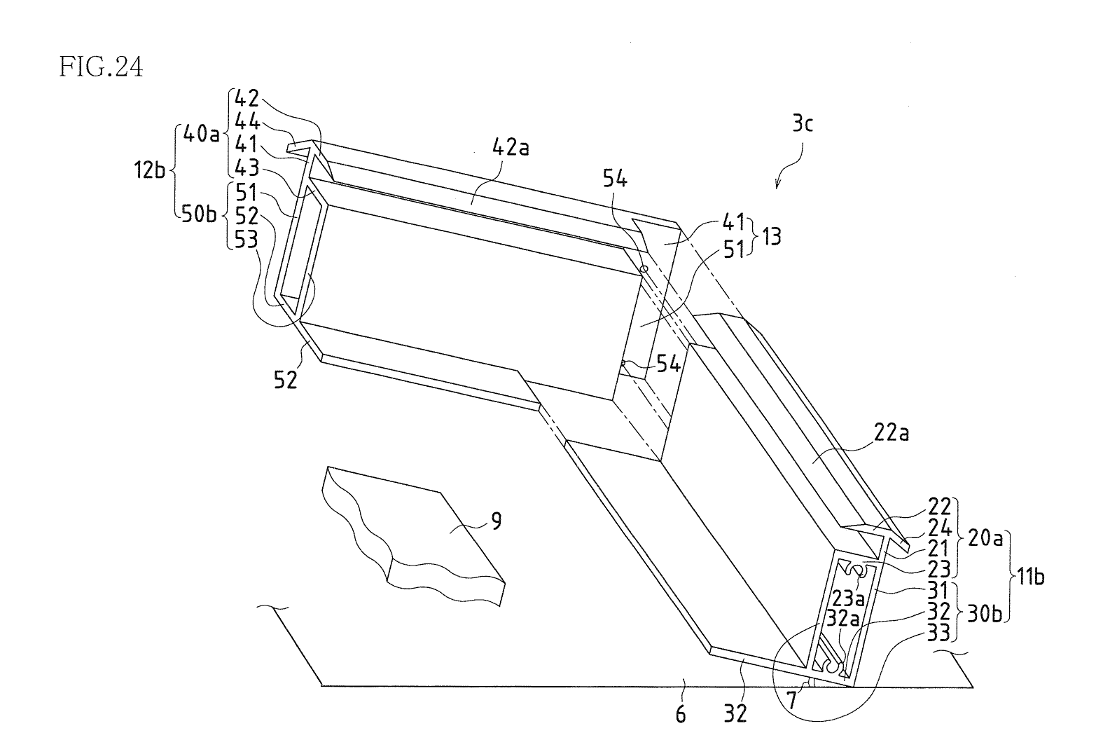

As an alternative, instead of using the sub-frame members 12a of the solar cell module 3b, a solar cell module 3c that uses sub-frame members 12b as shown in FIGS. 23 and 24 may be configured. Here, FIG. 23 is a perspective view of a corner portion of the solar cell module 3c, and FIG. 24 is an exploded perspective view of the corner portion of the solar cell module 3c.

The sub-frame members 12b of the solar cell module 3c differ from the sub-frame members 12a of the solar cell module 3b in that while the sub-wall portions 50a of the sub-frame members 12a each include the sub-outer wall 51 and the sub-bottom piece 52, the sub-wall portions 50b of the sub-frame members 12b each include a sub-outer wall 51, a sub-bottom piece 52, and a sub-inner wall 53. In other respects, the sub-frame members 12b are the same as the sub-frame members 12a.

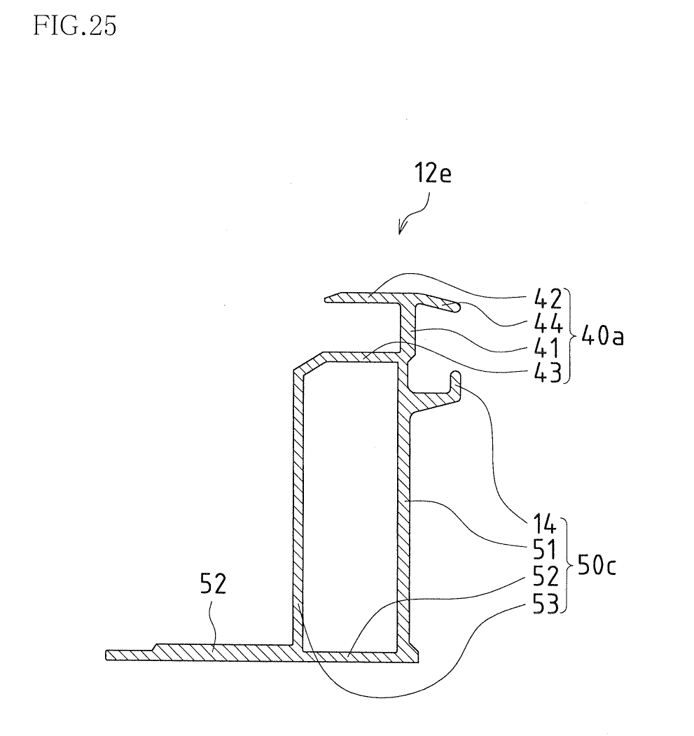

The solar cell module 3c may use a sub-frame member 12e having a cross-section as shown in FIG. 25, instead of the sub-frame members 12b. The sub-frame member 12e includes a sub-retaining portion 40a and a sub-wall portion 50c. The sub-frame member 12e has a hook piece 14 that projects from a sub-outer wall 51 of the sub-wall portion 50c and whose end is directed upward toward the outside.

By the use of the sub-frame member 12e with the hook piece 14, in cases where multiple solar cell modules 3c are installed so that their short sides are adjacent to one another, a space between the hook pieces 14 of the adjacent solar cell modules 3c may be fixed with a fastening fixture for installation or the like, which eases the formation of a gap between the sub-overhanging pieces 44.

Alternatively, no gap may be formed between the sub-overhanging pieces 44 in the case of using the sub-frame member 12e provided with the hook piece 14.

Also in the aforementioned solar cell modules (3a to 3c) as shown in FIGS. 16 to 25, a gap between sub-overhanging pieces 44 may be formed, or may not be formed, as described above.

In cases where a gap is formed between sub-overhanging pieces 44, retained rainwater is carried away in a direction perpendicular to the gradient by wind or the like, and rainwater containing dust or the like can effectively be discharged from the sub-frame member 12e side.

In cases where no gap is formed between sub-overhanging pieces 44, retained rainwater is carried away in a direction perpendicular to the gradient by wind or the like, and rainwater containing dust or the like flows into a groove-like portion formed by the sub-overhanging pieces 44 along the gradient and can effectively be discharged downward along the sub-frame members 12e.

Moreover, in the above-described solar cell modules (3a-3c), since the side end faces of the main retaining upper pieces 22 and the side end faces of the main overhanging pieces 24 are cut in alignment, as well as the side end faces of the upper sub-retaining pieces 42 and the side end faces of the sub-overhanging pieces being cut in alignment, as shown in FIGS. 16 to 25, the side end portions of the main overhanging pieces 24 and the side end portions of the sub-overhanging pieces 44 are not in contact with one another at the corners of the solar cell modules (3a-3c).

In this case, rectangular gaps surrounded by the side end portions of the main overhanging pieces 24 and the side end portions of the sub-overhanging pieces 44 are formed between adjacent solar cell modules (3a-3c). Thus, rainwater or the like flowing into the aforementioned groove-like portion formed by the sub-overhanging pieces 44 flows downward along the sub-frame members (12a, 12b) and can effectively be discharged downward through the rectangular gaps.

Also, in the above-described solar cell modules (3a-3c), although not shown in the drawings, the side end portions of the main overhanging pieces 24 and the side end portions of the sub-overhanging pieces 44 may be joined together, as described below. In other words, the main overhanging pieces 24 are extended from their side end portions so as to cover the top of the side end faces of the sub-retaining walls 41, and the side end portions of the main overhanging pieces 24 and the side end portions of the sub-overhanging pieces 44 are both extended projecting obliquely downward so that the side end portions of the main overhanging pieces 24 and the side end portions of the sub-overhanging pieces 44 are joined together.

This prevents a recessed portion from being formed at the corners of the solar cell modules (3a-3c) and thereby prevents the solar cell modules (3a-3c) from getting caught on something at the time of transportation, for example.

Furthermore, if the end of such a joined portion is removed and rounded, a gap can be formed between the ends of the joined portions of solar cell modules (3a-3c) that are installed adjacent to each other. This gap can be used similarly to the rectangular gap described above, enabling rainwater or the like to be effectively discharged downward through the gap.

### Embodiment 4

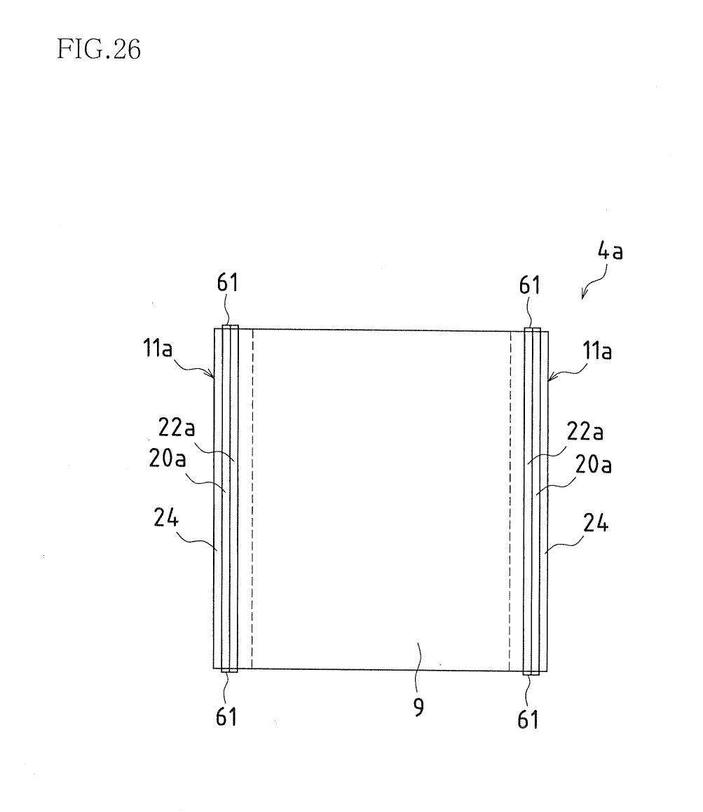

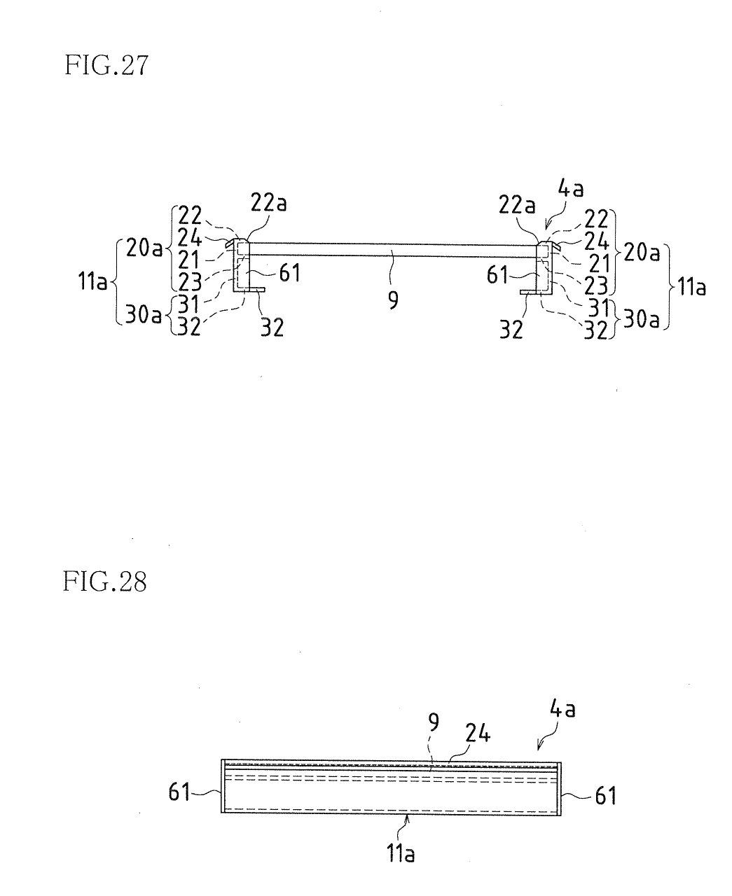

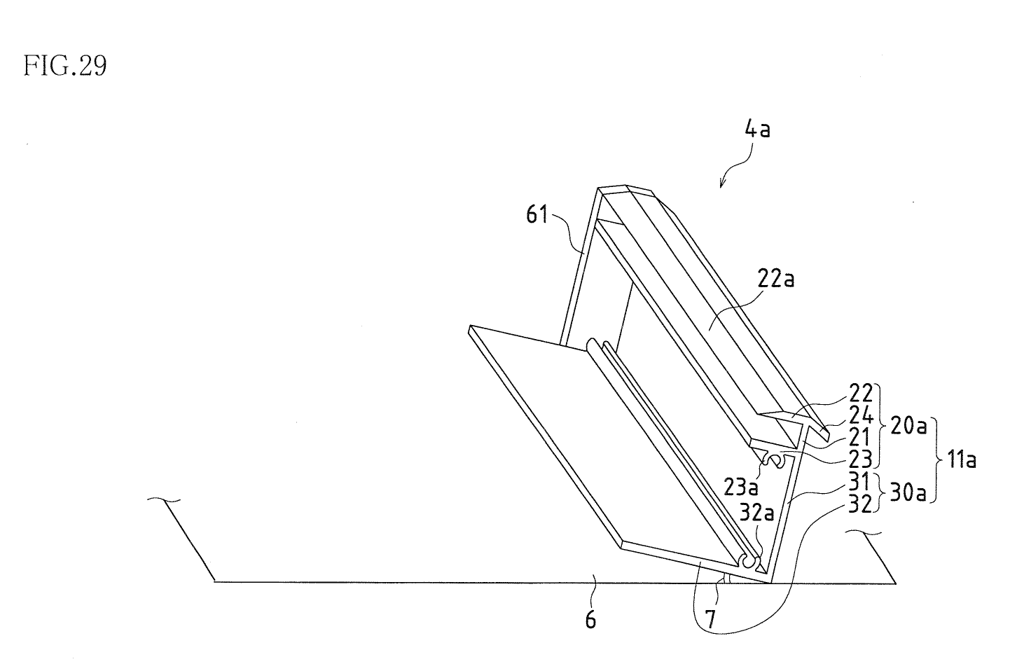

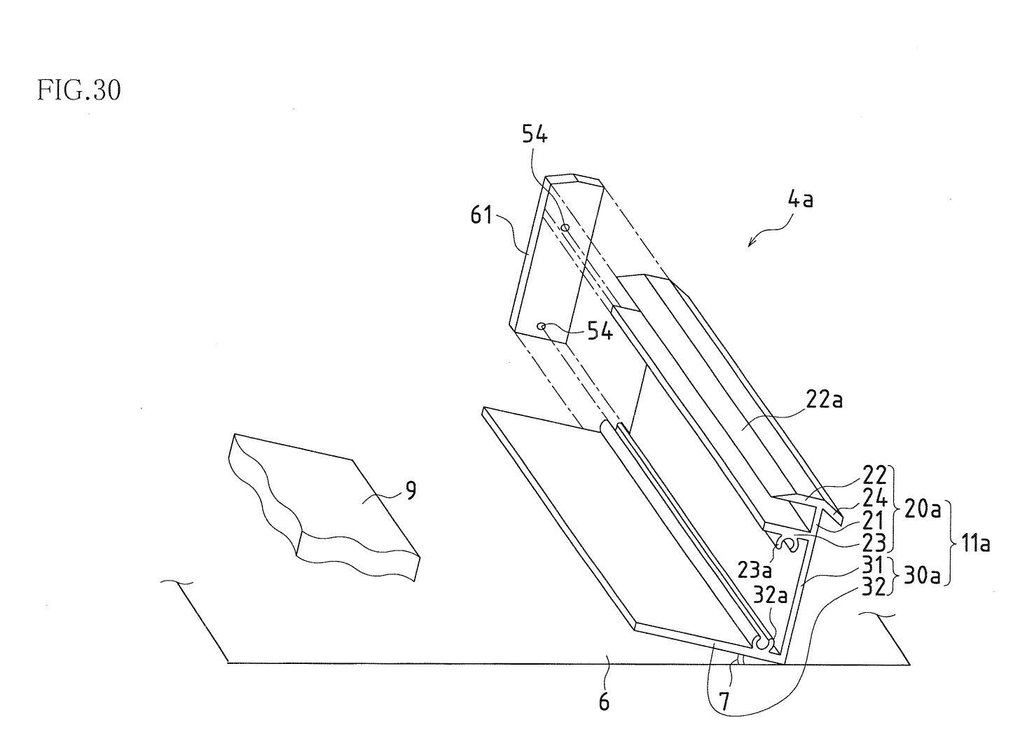

A solar cell module 4a according to Embodiment 4 is a partial modification of the aforementioned solar cell module 1a according to Embodiment 1. FIG. 26 is a plan view of the solar cell module 4a according to Embodiment 4, FIG. 27 is a front view thereof, FIG. 28 is a right side view thereof, FIG. 29 is a perspective view of a corner portion thereof, and FIG. 30 is an exploded perspective view of the corner portion. Note that a solar cell panel 9 is omitted in FIG. 29. FIGS. 29 and 30 show that the solar cell module 4a is inclined at an inclination angle 7 relative to a horizontal surface 6.

Specifically, the solar cell module 4a according to Embodiment 4 is installed at the inclination angle 7 at which water flow is stopped by surface tension, and more specifically, although depending on the surface condition, at a place such as a roof that is inclined at an angle of 0 to 45 degrees, preferably 0 to 30 degrees, and along the inclination of such a roof so that one of a pair of main frame members 11a is positioned lower than the other.

The solar cell module 4a according to Embodiment 4 differs from the solar cell module 1a according to Embodiment 1 in that while the solar cell module 1a according to Embodiment 1 uses the pair of sub-frame members 12c in addition to the pair of main frame members 11a, the solar cell module 4a according to Embodiment 4 uses only a pair of main frame members 11a and 11a and main frame side plates 61 that are attached to the pair of main frame members 11a, without using sub-frame members 12c. In other respects, the solar cell module 4a is the same as the solar cell module 1a according to Embodiment 1.

Since the sub-frame members 12c are not being used as described above, the solar cell module 4a is configured to retain the solar cell panel 9 with only the main frame members 11a. In the solar cell module 4a, the main frame members 11a are each provided with a main frame side plate 61 that covers the side end face of the main retaining portion 20a of the main frame member 11a and the side end face of an edge portion of the solar cell panel 9 that is fitted in the main retaining portion 20a.

The main frame side plates 61 prevents the solar cell panel 9 from being detached from the main frame members 11a. Moreover, the solar cell panel 9 is fixed to the main frame members 11a with an adhesive.

According to the solar cell module 4a, it is possible to configure the solar cell module 4a that retains the solar cell panel 9 with only the main frame members 11a and thereby to suppress an increase in the manufacturing cost of the solar cell module 4a.

Accordingly, it is possible to manufacture the solar cell module 4a that can prevent water flowing over the surface of the solar cell panel 9 from collecting on the surface of the solar cell module 4a, while reducing the manufacturing cost. In addition, the solar cell module 4a has almost similar functions and effects to those of the solar cell module 1a according to Embodiment 1.

Moreover, in addition to measures as described below, substantially the same various measures as those described with the aforementioned solar cell module 1a according to Embodiment 1 can also be carried out on the solar cell module 4a.

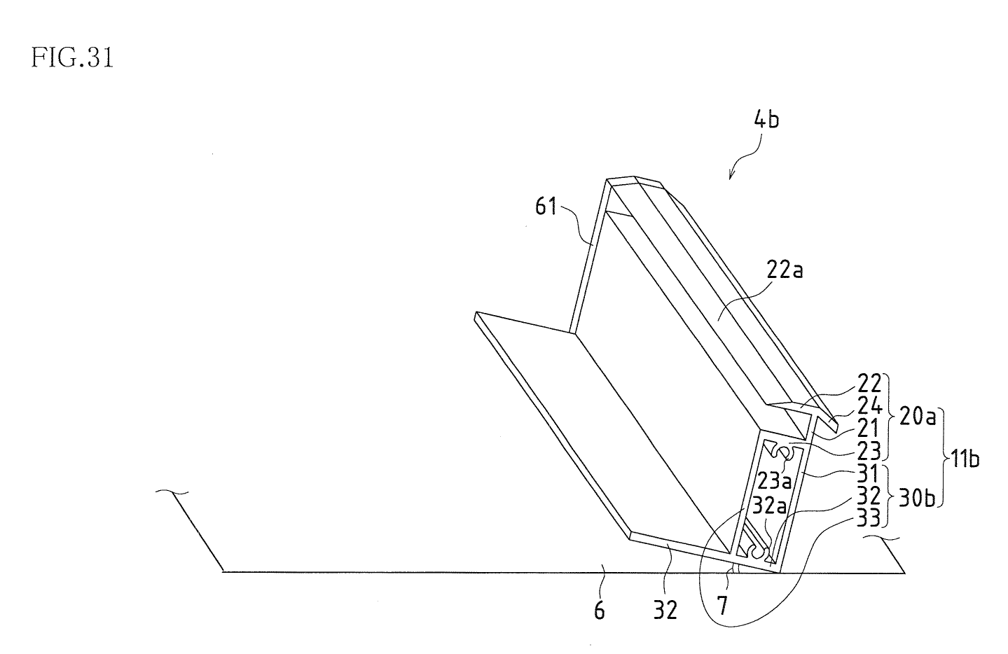

Instead of using the main frame members 11a of the solar cell module 4a, a solar cell module 4b that uses main frame members 11b as shown in FIGS. 31 and 32 may be configured. Here, FIG. 31 is a perspective view of a corner portion of the solar cell module 4b, and FIG. 32 is an exploded perspective view of the corner portion of the solar cell module 4b.

The main frame members 11b of the solar cell module 4b differ from the main frame members 11a of the solar cell module 4a in that while the main wall portions 30a of the main frame members 11a each include the main outer wall 31 and the main bottom piece 32, main wall portions 30b of the main frame members 11b each include a main outer wall 31, a main bottom piece 32, and a main inner wall 33. In other respects, the main frame members 11b are the same as the main frame members 11a.

### Embodiment 5

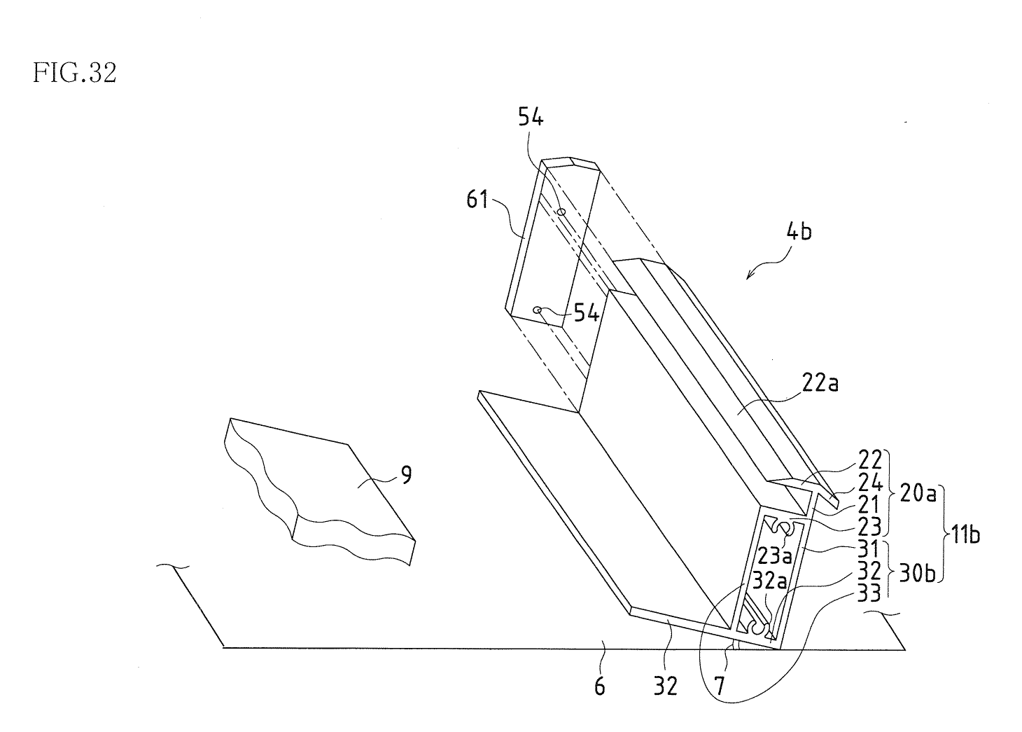

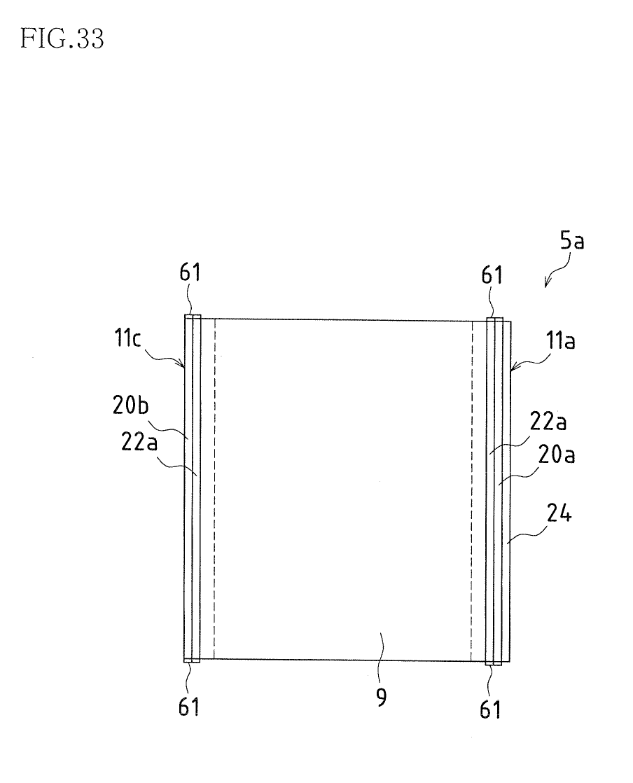

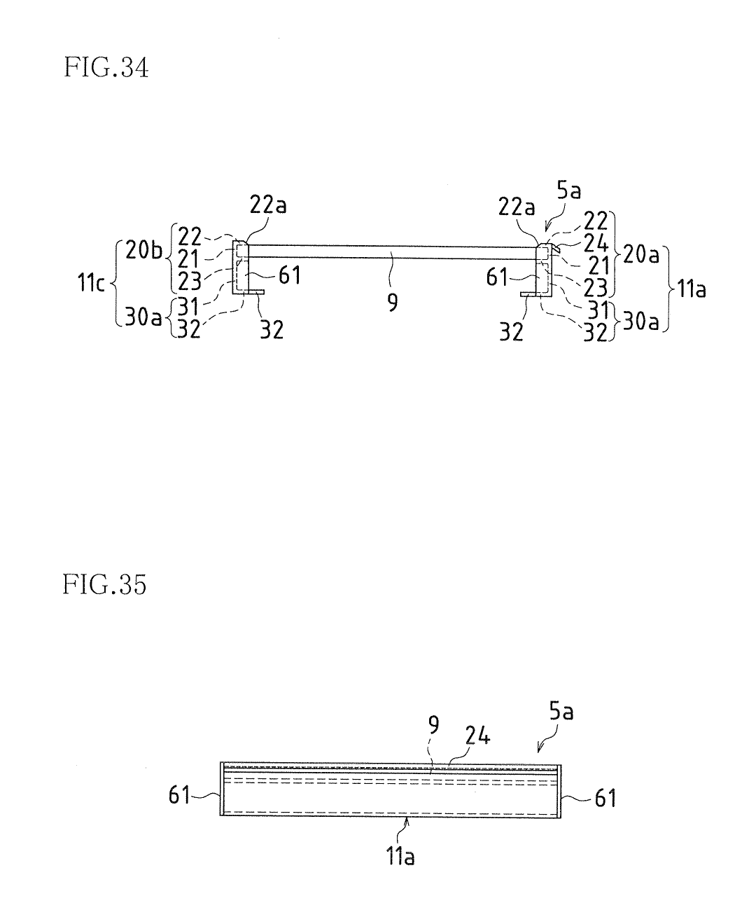

A solar cell module 5a according to Embodiment 5 is a partial modification of the aforementioned solar cell module 4a according to. Embodiment 4. FIG. 33 is a plan view of the solar cell module 5a according to Embodiment 5, FIG. 34 is a front view thereof, and FIG. 35 is a right side view thereof.

The solar cell module 5a according to Embodiment 5 differs from the solar cell module 4a according to Embodiment 4 in that while in the solar cell module 4a according to Embodiment 4, the main overhanging pieces 24 are formed on the main retaining portions 20a of both of the pair of main frame members 11a, a main overhanging piece 24 is formed on a main retaining portion 20a of only one main frame member 11a from among a pair of main frame members 11a and 11c in the solar cell module 5a according to Embodiment 5. In other respects, the solar cell module 5a is the same as the solar cell module 4a according to Embodiment 4.

Accordingly, the solar cell module 5a has almost similar functions and effects to those of the solar cell module 4a according to Embodiment 4. In addition, almost similar measures as those performed on the solar cell module 4a can also be carried out on the solar cell module 5a.

In each of the embodiments described above, the solar cell module may be formed with the configurations of the main frame members and the sub-frame members reversed.

In the solar cell module according to each of the aforementioned embodiments, it is also possible to use any one of main retaining portions 20c, 20d, 20e, 20f, 20g, and 20h described below, instead of the main retaining portions (20a, 20b) of the main frame members (11a-11d).

Among the above, the main retaining portions 20c, 20d, and 20e are provided with main overhanging pieces, and the main retaining portions 20f, 20g, and 20h are not provided with main overhanging pieces.

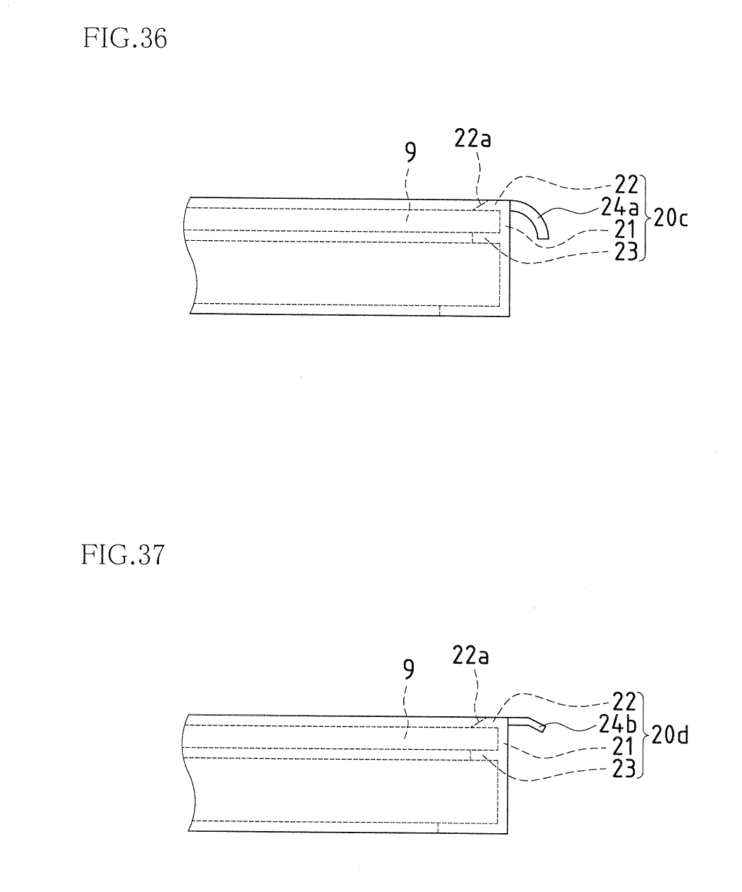

In FIGS. 36 to 41, which are explanatory drawings of those main retaining portions as described below, while a main wall portion 30a is used for the sake of convenience as a main wall portion of a main frame member, other main wall portions of the solar cell modules described in the above embodiments may be used instead.

FIG. 36 is an explanatory drawing showing the structure of the main retaining portion 20c. The main retaining portion 20c includes a main overhanging piece 24a that projects downward toward the outside from the upper end of a main retaining wall 21 so as to curve outwardly.

In the main retaining portion 20c, the upper surface of the main overhanging piece 24a and the upper surface of the main retaining upper piece 22 communicate with each other, and there is no angular edge between the main overhanging piece 24a and the main retaining upper piece 22. Thus, water is less likely to collect on the upper surface of the main retaining upper piece 22 due to surface tension.

FIG. 37 is an explanatory drawing showing the structure of the retaining portion 20d. The main retaining portion 20d includes a main overhanging piece 24b. The main overhanging piece 24b is shaped such that a main retaining upper piece 22 extends outward from the upper end of a main retaining wall 21 and its end inclines downward toward the outside.

With the main retaining portion 20d, the distance that the end inclines downward can be reduced, thus reducing the difference in levels and enabling the buildup of snow on the surface serving as the light-receiving surface of the solar cell panel 9 during snowfall to be reduced.

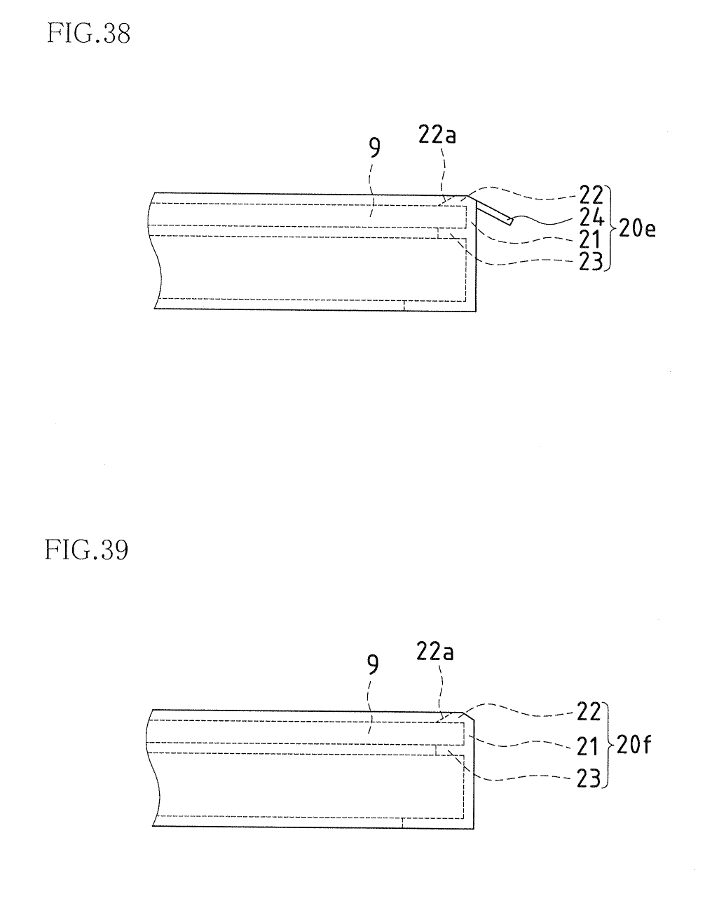

FIG. 38 is an explanatory drawing showing the structure of the main retaining portion 20e. In the main retaining portion 20e, the upper end edge of a main retaining wall 21, from which the main overhanging piece 24 inclines downward toward the outside, inclines as is the main overhanging piece 24, and this inclination surface is connected from the upper end edge of the main retaining wall 21 to the main overhanging piece 24.

The main retaining portion 20e increases the distance in which the end inclines downward, having a great difference in level. Thus, in cases where the solar cell module is installed on a roof, rainwater or the like containing dust from the ridge side of the solar cell module can effectively be discharged downward without being transmitted to the eaves side of the solar cell module.

FIG. 39 is an explanatory drawing showing the structure of the main retaining portion 20f. As described above, the main retaining portion 20f is not provided with a main overhanging piece, and the upper end edge of a main retaining wall 21 inclines downward toward the outside. This brings about similar functions and effects to those in the case of using main overhanging pieces.

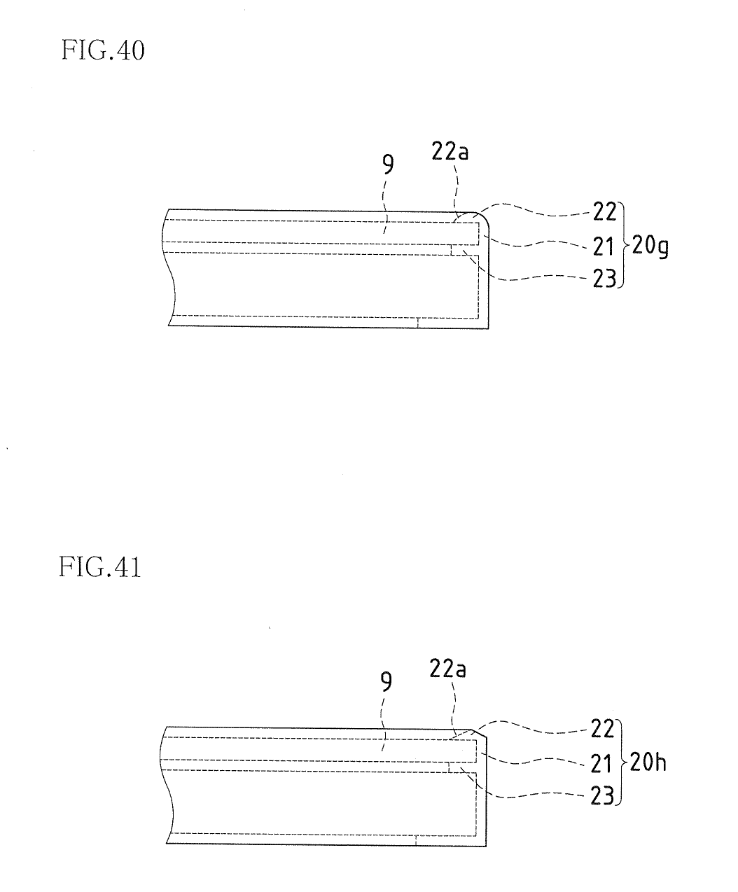

FIG. 40 is an explanatory drawing showing the structure of the main retaining portion 20g. Like the main retaining portion 20f, the main retaining portion 20g is not provided with a main overhanging piece, and the upper end edge of a main retaining wall 21 curves downward toward the outside so as to expand outwardly. This brings about similar functions and effects to those in the case of using main overhanging pieces.

In addition, in the main retaining portion 20g, an upper piece end face 22a curves downward toward the inside so as to bulge inwardly, instead of being inclined linearly. This curve of the upper piece end face 22a is connected to the curve of the upper end edge of the main retaining wall 21.

FIG. 41 is an explanatory drawing showing the structure of the main retaining portion 20h. Like the main retaining portion 20f, the main retaining portion 20h is not provided with a main overhanging piece, and the upper end edge of a main retaining wall 21 inclines downward toward the outside. This brings about similar functions and effects to those in the case of using main overhanging pieces.

The main retaining portion 20h differs from the main retaining portion 20f in that while the main retaining portion 20f has a flat surface between the inclined upper end edge of the main retaining wall 21 and the upper piece end face 22a, the main retaining portion 20h has no such flat surface.

The aforementioned modifications of the main retaining portions (20a, 20b) of the main frame members (11a-11d) are also applicable in a similar way to the sub-frame members (12a-12e) of the solar cell module according to each of the above embodiments.

Moreover, in each of the above embodiments, the solar cell module may be formed with the configurations of the main frame members and the sub frame members reversed with respect to the short and long sides of the solar cell panel 9. It is also apparent that all of the above descriptions are applicable to a solar cell module whose sides are equal in length and thus has no distinction between long and short sides.

The present invention can be implemented in various other forms without departing from the spirit or principal features of the present invention. The embodiments described above are therefore nothing more than illustrative in every respect, and should not be interpreted in a limiting way. The scope of the present invention is defined by the claims, and is not intended to be restricted by the foregoing specification in any way. Furthermore, all variations and modifications within the range of equivalence of the claims are encompassed in the scope of the present invention.

This application claims priority on Japanese Patent Application No. 2008-001692 filed in Japan on Jan. 8, 2008, the entire contents of which are herein incorporated by reference. All of the literature cited above is hereby specifically incorporated by reference.

### INDUSTRIAL APPLICABILITY

The solar cell module of the present invention is beneficial in that, when installed in places with gradual inclines such as a gently sloping roof, it can prevent water flowing over the surface of the solar cell module from collecting on the surface of the solar cell module.

1. A solar cell module comprising at least a pair of main frame members that retain a pair of opposing main sides of a solar cell panel and being configured to be installed with an inclination so that one of the main frame members is positioned lower than the other,
the main frame members each comprising a main retaining portion and a main wall portion that is connected to and extends downward below the main retaining portion,
the main retaining portion including a main retaining wall that runs along a main side of the solar cell panel, and a main retaining upper piece and a main retaining lower piece that project inwardly from upper and lower ends of the main retaining wall, respectively, and engage and retain an edge portion of the main side of the solar cell panel therebetween,
wherein at least the one of the main frame members that is positioned lower than the other is provided with a main overhanging piece that projects from the upper end of the main retaining wall of the main retaining portion with a downward inclination toward the outside and whose upper surface communicates with an upper surface of the main retaining upper piece.

2. The solar cell module according to claim 1, wherein both of the main frame members are provided with the main overhanging piece.

3. The solar cell module according to claim 2, wherein the solar cell module is installed at a plurality of locations adjacent to one another so that ends of the main overhanging pieces of the main frame members of the solar cell modules are located in close proximity and that a gap is formed between the ends of the main overhanging pieces of the main frame members of adjacent ones of the solar cell modules.

4. A solar cell module comprising at least a pair of main frame members that retain a pair of opposing main sides of a solar cell panel and being configured to be installed with an inclination so that one of the main frame members is positioned lower than the other,
the main frame members each comprising a main retaining portion, and a main wall portion that is connected to and extends downward below the main retaining portion,
the main retaining portion including a main retaining wall that runs along a main side of the solar cell panel, and a main retaining upper piece and a main retaining lower piece that project inward from upper and lower ends of the main retaining wall, respectively, and engage and retain an edge portion of the main side of the solar cell module therebetween,
wherein the main retaining upper piece of at least the one of the main frame members that is positioned lower than the other has a base end whose upper surface inclines downward toward the outside.

5. The solar cell module according to claim 4, wherein the main retaining upper pieces of both of the main frame members have a base end whose upper surface inclines downward toward the outside.

6. The solar cell module according to claim 5, wherein the solar cell module is installed at a plurality of locations adjacent to one another so that the main frame members of the solar cell modules are located in close proximity and that a gap is formed between the main frame members of adjacent ones of the solar cell modules.

7. The solar cell module according to claim 1, wherein the main retaining upper pieces of the main frame members have an inner end whose upper surface inclines downward toward the inside.

8. The solar cell module according to claim 1, wherein the main frame members each comprise a main frame side plate that covers a side end face of the main retaining portion of the main frame member and a side end face of the edge portion of the solar cell panel fitted in the main retaining portion.

9. The solar cell module according to claim 1, comprising:
a pair of sub-frame members that retain a pair of adjoining sides that adjoin the main sides of the solar cell panel,
the sub-frame members each comprising a sub-retaining portion and a sub-wall portion that is connected to and extends downward below the sub-retaining portion,
the sub-retaining portion including a sub-retaining wall that runs along an adjoining side of the solar cell panel, and an upper sub-retaining piece and a lower sub-retaining piece that project inward from upper and lower ends of the sub-retaining wall, respectively, and engage and retain an edge portion of the adjoining side of the solar cell panel therebetween,
wherein at least one of the sub-frame members is provided with a sub-overhanging piece that projects from the upper end of the sub-retaining wall of the sub-retaining portion with a downward inclination toward the outside and whose upper surface communicates with an upper surface of the upper sub-retaining piece.

10. The solar cell module according to claim 9, wherein both of the sub-frame members are provided with the sub-overhanging piece.

11. The solar cell module according to claim 10, wherein the solar cell module is installed at a plurality of locations adjacent to one another so that ends of the sub-overhanging pieces of the sub-frame members of the solar cell modules are located in close proximity and that a gap is formed between the ends of the sub-overhanging pieces of the sub-frame members of adjacent ones of the solar cell modules.

12. The solar cell module according to claim 4, comprising:
a pair of sub-frame members that retain a pair of adjoining sides that adjoin the main sides of the solar cell panel,
the sub-frame members each comprising a sub-retaining portion and a sub-wall portion that is connected to and extends downward below the sub-retaining portion,
the sub-retaining portion including a sub-retaining wall that runs along an adjoining side of the solar cell panel, and an upper sub-retaining piece and a lower sub-retaining piece that project inward from upper and lower ends of the sub-retaining wall, respectively, and engage and retain an edge portion of the adjoining side of the solar cell panel therebetween,
wherein the upper sub-retaining piece of at least one of the sub-frame members has a base end whose upper surface inclines downward toward the outside.

13. The solar cell module according to claim 12, wherein the upper sub-retaining pieces of both of the sub-frame members have a base end whose upper surface inclines downward toward the outside.

14. The solar cell module according to claim 13, wherein the solar cell module is installed at a plurality of locations adjacent to one another so that the sub-frame members of the solar cell modules are located in close proximity and that a gap is formed between the sub-frame members of adjacent ones of the solar cell modules.

15. The solar cell module according to claim 9, wherein the upper sub-retaining pieces of the sub-frame members have an inner end whose upper surface inclines downward toward the inside.

16. The solar cell module according to claim 4, wherein the main retaining upper pieces of the main frame members have an inner end whose upper surface inclines downward toward the inside.

17. The solar cell module according to claim 4, wherein the main frame members each comprise a main frame side plate that covers a side end face of the main retaining portion of the main frame member and a side end face of the edge portion of the solar cell panel fitted in the main retaining portion.

18. The solar cell module according to claim 12, wherein the upper sub-retaining pieces of the sub-frame members have an inner end whose upper surface inclines downward toward the inside.
